(19) United States
(12) Patent Application Publication
(10) Pub. No.: US 2026/0098143 A1
(43) Pub. Date: Apr. 9, 2026

(54) RESIN COMPOSITION, AND PREPREG, RESIN-EQUIPPED FILM, RESIN-EQUIPPED METAL FOIL, METAL-CLAD LAMINATED PLATE, AND WIRING BOARD USING SAID RESIN COMPOSITION

(71) Applicant: PANASONIC INTELLECTUAL PROPERTY MANAGEMENT CO., LTD., Osaka (JP)

(72) Inventors: Hirosuke SAITO, Osaka (JP); Takahito HAGIWARA, Osaka (JP); Keiko KASHIHARA, Osaka (JP)

(73) Assignee: PANASONIC INTELLECTUAL PROPERTY MANAGEMENT CO., LTD., Osaka (JP)

(21) Appl. No.: 19/128,026

(22) PCT Filed: Oct. 10, 2023
(86) PCT No.: PCT/JP2023/036787

§ 371 Date: May 7, 2025

(30) Foreign Application Priority Data
Nov. 11, 2022 (JP) 2022-180985

(51) Int. Cl. C08K 5/5313; B32B 15/082; B32B 27/20; B32B 27/30; C08J 5/24; C08L 25/08; C08L 71/12; H05K 1/03

(52) U.S. Cl. CPC C08K 5/5313; B32B 15/082; B32B 27/20; B32B 27/302; C08J 5/249; C08L 25/08; C08L 71/126; H05K 1/0366; B32B 2250/02; B32B 2264/1021; B32B 2307/3065; B32B 2457/08; C08J 2325/08; C08J 2371/12; C08J 2425/06; C08J 2425/08; C08J 2465/02; C08J 2471/12; C08L 2203/20; C08L 2205/025; C08L 2205/035

(57) ABSTRACT

A resin composition contains a compound (A) containing at least one selected from a polyfunctional vinyl aromatic copolymer (A-1), which has a repeating unit (a1) derived from a divinyl aromatic compound and a repeating unit (a2) derived from a monovinyl aromatic compound and contains the repeating unit (a1) at 2 mol % or more and less than 95 mol % and the repeating unit (a2) at 5 mol % or more and less than 98 mol % when the total of the repeating unit (a1) and the repeating unit (a2) is set to 100 mol %, or a hydrocarbon-based compound (A-2) represented by Formula (1); and a phosphorus-containing compound (B) represented by Formula (2).

### TECHNICAL FIELD

The present invention relates to a resin composition and a prepreg, a film with resin, a metal foil with resin, a metal-clad laminate, and a wiring board, which are obtained using the resin composition.

### BACKGROUND ART

In recent years, along with an increased amount of information processed, various electronic devices have rapidly progressed in mounting technologies such as higher integration of semiconductor devices to be mounted, higher density for wiring, and multi-layering. A thermosetting resin is generally used as a substrate material for constituting a base material of a wiring board used in various electronic devices, and is required to have high heat resistance (glass transition temperature) in order to respond to multilayering and a high temperature condition in a process such as reflow, and also required to have a low dielectric constant and a low dielectric loss tangent in order to increase a signal transmission speed and reduce a loss during signal transmission.

Since a substrate material for a printed wiring board or a semiconductor package is required to have high flame retardancy, a flame retardant is generally added to a resin composition used as an insulating material of the substrate material. As the flame retardant, a halogen-based flame retardant such as a bromine-based flame retardant and the like are also known, but a cured product of such resin composition containing a halogen may produce a harmful substance such as hydrogen halide at the time of combustion, and has a disadvantage of negatively affecting humans and the natural environment. Because of this situation, an insulating material for printed wiring boards also are required to be halogen-free.

A phosphorus-based flame retardant known as a non-halogen flame retardant is assumed to exhibit a flame retardant effect by the promotion effects of a phosphorus compound on the carbonization of a synthetic resin to turn the surface thereof into a char layer during combustion thereby shielding thermal energy of an ignition source or shielding air required for combustion.

Hitherto, it has been reported that flame retardancy can be secured while the performance as a printed wiring board is maintained to some extent by adding a predetermined phosphorus compound to a thermosetting resin such as a PPE compound or a maleimide compound (Patent Literatures 1 and 2).

Among conventional non-halogen flame retardants, phosphorus-based flame retardants as described in the literatures are said to realize flame retardancy by the promotion effects of a phosphorus compound on the carbonization of a synthetic resin to turn the surface thereof into a char layer during combustion thereby shielding thermal energy of an ignition source or shielding air required for combustion.

Patent Literature 1 discloses that flame retardancy can be secured while the performance as a printed wiring board is maintained to some extent by adding a predetermined phosphorus compound to a thermosetting resin such as a polyphenylene ether copolymer. Patent Literature 2 discloses that a resin composition, in which a polyfunctional vinyl aromatic copolymer is used as a lower dielectric resin and a specific phosphorus-containing flame retardant is contained, can secure lower dielectricity and high flame retardancy.

However, there is a demand for a technique that can realize a low dielectric loss tangent capable of supporting the high frequencies required for recent high speed communications while securing much higher flame retardancy than conventional phosphorus-based compounds as disclosed in the literatures.

The present invention is made in view of such circumstances, and an object thereof is to provide a resin composition affording a cured product that can achieve high flame retardancy as well as exhibits low dielectric properties. Another object of the present invention is to provide a prepreg, a film with resin, a metal foil with resin, a metal-clad laminate, and a wiring board, which are obtained using the resin composition.

### CITATION LIST

### Patent Literatures

Patent Literature 1: JP 2011-46816 A
Patent Literature 2: JP 2020-105352 A

### SUMMARY OF INVENTION

The resin composition according to an aspect of the present invention contains a compound (A) containing at least one selected from a polyfunctional vinyl aromatic copolymer (A-1), which has a repeating unit (a1) derived from a divinyl aromatic compound and a repeating unit (a2) derived from a monovinyl aromatic compound and contains the repeating unit (a1) at 2 mol % or more and less than 95 mol % and the repeating unit (a2) at 5 mol % or more and less than 98 mol % when a total of the repeating unit (a1) and the repeating unit (a2) is set to 100 mol %, or a hydrocarbon-based compound (A-2) represented by the following Formula (1); and a phosphorus-containing compound (B) represented by the following Formula (2).

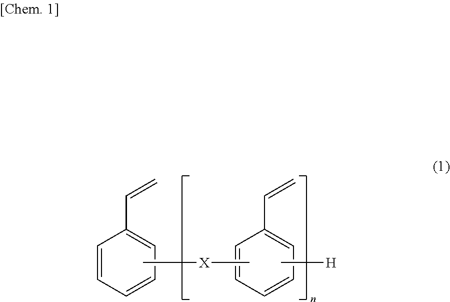

(In Formula (1), X represents a hydrocarbon group having 6 or more carbon atoms, which contain at least one selected from an aromatic cyclic group or an aliphatic cyclic group, and n represents an integer from 1 to 10.)

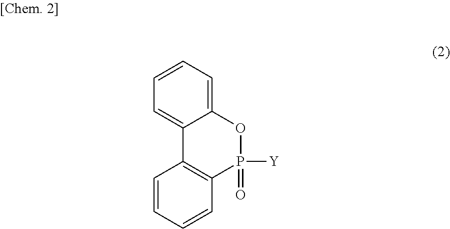

(In Formula (2), Y is a protecting group.)

### BRIEF DESCRIPTION OF DRAWINGS

FIG. 1 is a schematic sectional view illustrating the configuration of a prepreg according to an embodiment of the present invention.

FIG. 2 is a schematic sectional view illustrating the configuration of a metal-clad laminate according to an embodiment of the present invention.

FIG. 3 is a schematic sectional view illustrating the configuration of a wiring board according to an embodiment of the present invention.

FIG. 4 is a schematic sectional view illustrating the configuration of a metal foil with resin according to an embodiment of the present invention.

FIG. 5 is a schematic sectional view illustrating the configuration of a film with resin according to an embodiment of the present invention.

FIG. 6 illustrates a GPC chart of the compound obtained in Synthesis Example 1.

FIG. 7 illustrates a ¹H-NMR chart of the compound obtained in Synthesis Example 1.

FIG. 8 illustrates a GPC chart of the compound obtained in Synthesis Example 2.

FIG. 9 illustrates a ¹H-NMR chart of the compound obtained in Synthesis Example 2.

### DESCRIPTION OF EMBODIMENTS

The resin composition according to an embodiment of the present invention (hereinafter, also simply referred to as the resin composition) contains a compound (A) containing at least one selected from a polyfunctional vinyl aromatic copolymer (A-1), which has a repeating unit (a1) derived from a divinyl aromatic compound and a repeating unit (a2) derived from a monovinyl aromatic compound and contains the repeating unit (a1) at 2 mol % or more and less than 95 mol % and the repeating unit (a2) at 5 mol % or more and less than 98 mol % when the total of the repeating unit (a1) and the repeating unit (a2) is set to 100 mol %, or a hydrocarbon-based compound (A-2) represented by Formula (1); and a phosphorus-containing compound (B) represented by Formula (2).

As the resin composition of the present embodiment contains the compound (A) containing at least one selected from the polyfunctional vinyl aromatic copolymer (A-1) or the hydrocarbon-based compound (A-2), a cured product of the resin composition can exhibit low dielectric properties. As the resin composition contains the phosphorus-containing compound (B), the cured product also exhibits excellent flame retardancy. In other words, according to the present invention, it is possible to provide a resin composition affording a cured product that exhibits low dielectric properties and flame retardancy in an excellently balanced manner. By using the resin composition, it is possible to provide a prepreg, a film with resin, a metal foil with resin, a metal-clad laminate, and a wiring board, which are excellent in the properties.

Furthermore, in order to maintain high reliability as electronic material properties, heat resistance is also required in addition to the properties. It is considered that the resin composition of the present embodiment also exhibits excellent heat resistance by the configuration.

A material imparting a high Tg to the cured product is one of the factors for further improvement in heat resistance (solder heat resistance, reflow heat resistance, and the like). A material imparting a high Tg to the cured product has also an advantage that the coefficient of thermal expansion of the material is a small value in a temperature region from room temperature to reflow or solder temperature. This is because thermal expansion generally increases sharply at a temperature exceeding the glass transition temperature. In other words, when the glass transition temperature is low, the coefficient of thermal expansion increases in a high temperature region exceeding the glass transition temperature. When the glass transition temperature is low, the thermal expansion in a higher temperature region is greater, and for example, troubles such as warpage may occur and connection reliability may decrease in the wiring board. According to the configuration of the present embodiment as described above, it is considered that a resin composition also having a high Tg can be provided.

Hereinafter, the respective components of the resin composition according to the present embodiment will be specifically described.

The compound (A) used in the present embodiment contains at least one selected from the polyfunctional vinyl aromatic copolymer (A-1) or a hydrocarbon-based compound (A-2).

### <Polyfunctional Vinyl Aromatic Polymer (A-1)>

The polyfunctional vinyl aromatic polymer (A-1) used in the resin composition of the present embodiment has a repeating unit (a1) derived from a divinyl aromatic compound and a repeating unit (a2) derived from a monovinyl aromatic compound and contains the repeating unit (a1) at 2 mol % or more and less than 95 mol % and the repeating unit (a2) at 5 mol % or more and less than 98 mol % when the total of the repeating unit (a1) and the repeating unit (a2) is set to 100 mol %.

The polyfunctional vinyl aromatic copolymer (A-1) further contains a repeating unit (a1-1) represented by the following Formula (a1-1) as a part of the repeating unit (a1) derived from a divinyl aromatic compound.

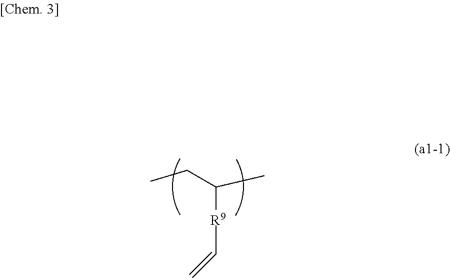

In Formula (a1-1), R⁹ represents an aromatic hydrocarbon group having 6 to 30 carbon atoms.

In the polyfunctional vinyl aromatic copolymer (A-1), the repeating unit (a1) is contained at 2 mol % or more and less than 95 mol % and the repeating unit (a2) is contained at 5 mol % or more and less than 98 mol % when the total of the repeating unit (a1) and the repeating unit (b) is set to 100 mol %. The repeating unit (a1-1) is preferably contained at 2 to 80 mol % when the total of the repeating unit (a1) and the repeating unit (a2) is set to 100 mol %.

It is preferable that the number average molecular weight Mn of the polyfunctional vinyl aromatic copolymer (A-1) is 300 to 100,000 and the molecular weight distribution, which is expressed as the ratio of the weight average molecular weight Mw to the number average molecular weight, is 100.0 or less. The polyfunctional vinyl aromatic copolymer (A-1) is preferably soluble in toluene, xylene, tetrahydrofuran, dichloroethane or chloroform.

The polyfunctional vinyl aromatic copolymer (A-1) is not particularly limited, but examples thereof include a copolymer, which is represented by the following Formula (6) and contains structural units derived from the repeating unit (a1) derived from a divinyl aromatic compound and the repeating unit (a2) derived from a monovinyl aromatic compound. These structural units may be arranged regularly or randomly.

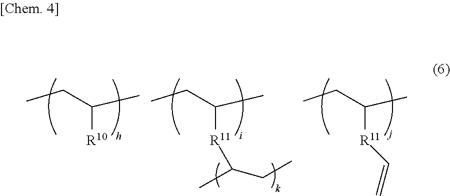

In Formula (6), R¹⁰ is an aromatic hydrocarbon group having 6 to 30 carbon atoms, which is derived from a monovinyl aromatic compound, R¹¹ is an aromatic hydrocarbon group having 6 to 30 carbon atoms, which is derived from a divinyl aromatic compound, and h to k are each independently an integer from 0 to 200, provided that the total thereof is 2 to 20,000.

Preferably, the polyfunctional vinyl aromatic copolymer (A-1) is a copolymer composed of repeating units in which R¹⁰ and R¹¹ in Formula (6) are aromatic hydrocarbon groups selected from the group consisting of a phenyl group optionally having a substituent, a biphenyl group optionally having a substituent, a naphthalene group optionally having a substituent, and a terphenyl group optionally having a substituent.

The polyfunctional vinyl aromatic copolymer (A-1) is preferably soluble in a solvent. The repeating unit as used herein is derived from a monomer, and includes units that are present in the main chain of the copolymer and appear repeatedly and units or terminal groups that are present in the terminals or side chains. A repeating unit is also called a structural unit.

The structural unit (a1) derived from a divinyl aromatic compound is contained at 2 mol % or more and less than 95 mol % with respect to the total sum of a divinyl aromatic compound and the structural unit (a2) derived from a monovinyl aromatic compound. The structural unit (a1) derived from a divinyl aromatic compound can have a plurality of structures, such as one in which only one of two vinyl groups has reacted and one in which two of two vinyl groups have reacted, but among these, the repeating unit, in which only one vinyl group is reacted, represented by Formula (a1-1) is contained at preferably 2 to 80 mol %, more preferably 5 to 70 mol %, still more preferably 10% to 60%, particularly preferably 15% to 50% with respect to the total sum. It is considered that by setting the repeating unit content to 2 to 80 mol %, the dielectric loss tangent is low, heat resistance is excellent, and compatibility with other resins is excellent. The heat resistance tends to decrease when the repeating unit content is less than 2 mol %, and the adhesive strength tends to decrease when the repeating unit content exceeds 80 mol %.

The polyfunctional vinyl aromatic copolymer (A-1) contains the structural unit (a2) derived from a monovinyl aromatic compound at 5 mol % or more and less than 98 mol % with respect to the total sum. The structural unit (a2) is contained at more preferably 10 mol % or more and less than 90 mol %. The content of the structural unit (a2) is still more preferably 15 mol % or more and less than 85 mol %. The molding processability may be insufficient when the content of the structural unit (a2) is less than 5 mol %, and the heat resistance of the cured product may be insufficient when the content of the structural unit (a2) exceeds 98 mol %.

The vinyl group present in Formula (a1-1) acts as a crosslinking component and contributes to exertion of heat resistance of the polyfunctional vinyl aromatic copolymer (A-1). Meanwhile, the structural unit (a2) derived from a monovinyl aromatic compound does not have a vinyl group since it is considered that the polymerization usually proceeds through the 1,2-addition reaction of a vinyl group. In other words, the structural unit (a2) derived from a monovinyl aromatic compound does not act as a crosslinking component but contributes to exertion of moldability.

Examples of the monovinyl aromatic compound preferably include styrene. A monovinyl aromatic compound other than styrene can be used together with styrene. In this case, the content of the structural unit (a2-1) derived from styrene is preferably 99 to 20 mol % when the total content of the structural unit (a2-1) derived from styrene and the structural unit (a2-2) derived from a monovinyl aromatic compound other than styrene is set to 100 mol %. The content of the structural unit (a2-1) is more preferably 98 to 30 mol %. It is preferable that the content of (a2-1) is in the above range since both resistance to thermal oxidation deterioration and moldability are exhibited. The heat resistance tends to decrease in a case where the structural unit (a2-1) is more than 99 mol %, and the moldability tends to decrease in a case where the structural unit (a2-2) is more than 80 mol %.

The number average molecular weight (number average molecular weight in terms of standard polystyrene measured using GPC) of the polyfunctional vinyl aromatic copolymer (A-1) is preferably 300 to 100,000, more preferably 400 to 50,000, still more preferably 500 to 10,000. When the Mn is less than 300, the amount of the monofunctional copolymer component contained in the polyfunctional vinyl aromatic copolymer (A-1) increases, and the heat resistance of the cured product tends to decrease. When the Mn exceeds 100,000, gel is easily generated, the viscosity increases, and the molding processability tends to decrease. The value of the molecular weight distribution (Mw/Mn) expressed as the ratio of the weight average molecular weight (weight average molecular weight in terms of standard polystyrene measured using GPC) to Mn is 100.0 or less, preferably 50.0 or less, more preferably 1.5 to 30.0, most preferably 2.0 to 20.0. When the Mw/Mn exceeds 100.0, the processing characteristics of the polyfunctional vinyl aromatic copolymer (A-1) tend to be poor, and gel tends to be generated.

The divinyl aromatic compound plays a role in forming a branched structure and making the copolymer polyfunctional as well as plays a role as a crosslinking component for exerting heat resistance when the obtained polyfunctional vinyl aromatic copolymer (A-1) is heat-cured. Examples of the divinyl aromatic compound are not particularly limited as long as they are aromatic compounds having two vinyl groups, but divinylbenzene (including the respective regioisomers or mixtures thereof), divinylnaphthalene (including the respective regioisomers or mixtures thereof), and divinylbiphenyl (including the respective regioisomers or mixtures thereof) are preferably used. These can be used singly or in combination of two or more kinds thereof. Divinylbenzene (m-isomer, p-isomer, or a regioisomer mixture thereof) is more preferable from the viewpoint of molding processability.

Examples of the monovinyl aromatic compound include styrene and monovinyl aromatic compounds other than styrene. However, it is desirable to use styrene essentially and a monovinyl aromatic compound other than styrene concurrently.

Styrene plays a role in imparting low dielectric properties and resistance to thermal oxidation deterioration to the polyfunctional vinyl aromatic copolymer (A-1) as a monomer component as well as plays a role in controlling the molecular weight of the polyfunctional vinyl aromatic copolymer (A-1) as a chain transfer agent. The monovinyl aromatic compound other than styrene improves the solubility in solvent and processability of the polyfunctional vinyl aromatic copolymer (A-1).

Examples of the monovinyl aromatic compound other than styrene are not particularly limited as long as they are aromatic compounds having one vinyl group other than styrene, and include vinyl aromatic compounds such as vinylnaphthalene and vinylbiphenyl; and nuclear alkyl-substituted vinyl aromatic compounds such as o-methylstyrene, m-methylstyrene, p-methylstyrene, o,p-dimethylstyrene, o-ethylvinylbenzene, m-ethylvinylbenzene and p-ethylvinylbenzene. The monovinyl aromatic compound other than styrene is preferably ethylvinylbenzene (including the respective regioisomers or mixtures thereof), ethylvinylbiphenyl (including the respective regioisomers or mixtures thereof), or ethylvinylnaphthalene (including the respective regioisomers and mixtures thereof) since the compound prevents gelation of the polyfunctional vinyl aromatic copolymer (A-1), is highly effective in improving solubility in solvent and processability, is low in cost, and is readily available. From the viewpoints of dielectric properties and cost, ethylvinylbenzene (m-isomer, p-isomer or a regioisomer mixture thereof) is more preferable.

In addition to the divinyl aromatic compound and the monovinyl aromatic compound, structural units (b) derived from one or two or more other monomer components such as a trivinyl aromatic compound, a trivinyl aliphatic compound, a divinyl aliphatic compound, and a monovinyl aliphatic compound can be introduced into the polyfunctional vinyl aromatic copolymer (A-1) as long as the effects of the present invention are not impaired.

Examples of the other monomer components include 1,3,5-trivinylbenzene, 1,3,5-trivinylnaphthalene, 1,2,4-trivinylcyclohexane, ethylene glycol diacrylate, butadiene, 1,4-butanediol divinyl ether, cyclohexanedimethanol divinyl ether, diethylene glycol divinyl ether and triallyl isocyanurate. These can be used singly or in combination of two or more kinds thereof.

The mole fraction of the other monomer components is preferably less than 30 mol % with respect to the total sum of all monomer components. In other words, the mole fraction of the repeating unit (b) derived from other monomer components is preferably less than 30 mol % with respect to the total sum of the structural units (a1), (a2), and (b) derived from all the monomer components constituting the copolymer.

### <Hydrocarbon-Based Compound (A-2)>

The hydrocarbon-based compound (A-2) used in the resin composition of the present embodiment is a compound represented by the following Formula (1).

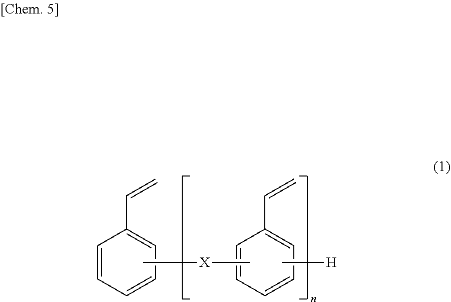

In Formula (1), X represents a hydrocarbon group having 6 or more carbon atoms, which includes at least one selected from an aromatic cyclic group or an aliphatic cyclic group. n represents an integer from 1 to 10.

The aromatic cyclic group is not particularly limited, but examples thereof include a phenylene group, a xylylene group, a naphthylene group, a tolylene group, and a biphenylene group.

The aliphatic cyclic group is not particularly limited, but examples thereof include a group containing an indane structure represented by the following Formula (7) and a group containing a cycloolefin structure.

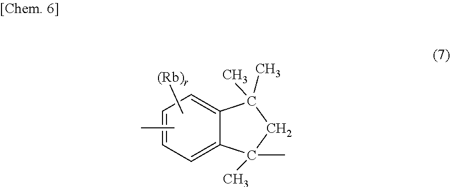

In Formula (7), Rb's are independent of each other. In other words, Rb's may be the same group as or different groups from each other, and for example, when r is 2 or 3, two or three Rb's bonded to the same benzene ring may be the same group as or different groups from each other. Rb represents an alkyl group having 1 to 10 carbon atoms, an alkyloxy group (alkoxy group) having 1 to 10 carbon atoms, an alkylthio group having 1 to 10 carbon atoms, an aryl group having 6 to 10 carbon atoms, an aryloxy group having 6 to 10 carbon atoms, an arylthio group having 6 to 10 carbon atoms, a cycloalkyl group having 3 to 10 carbon atoms, a halogen atom, a hydroxyl group, or a mercapto group (thiol group). r represents an integer from 0 to 3.

The number of carbon atoms in Formula (I) is not particularly limited as long as it is 6 or more, but is more preferably 6 or more and 20 or less from the viewpoint of maintaining a high Tg.

In a preferred embodiment, the hydrocarbon-based compound (A-1) of the present embodiment includes a hydrocarbon-based compound (A-2a) represented by the following Formula (5).

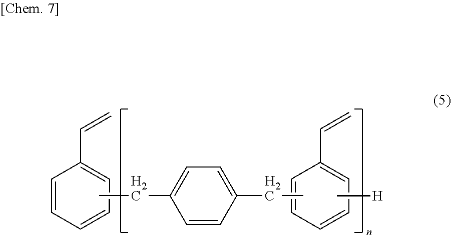

In Formula (5), n represents an integer from 1 to 10.

By containing such a hydrocarbon-based compound (A-2a), it is considered that the effects as described above can be attained more reliably.

In the resin composition of the present embodiment, the compound (A) is only required to contain at least one of the polyfunctional vinyl aromatic polymer (A-1) or the hydrocarbon-based compound (A-2), but in a preferred embodiment, it is desirable to contain both of these. This has the advantage that a cured product exhibiting flame retardancy and dielectric properties, glass transition temperature, and copper foil peel strength in an excellently balanced manner is obtained.

In a case where the resin composition of the present embodiment contains the polyfunctional vinyl aromatic polymer (A-1) and the hydrocarbon-based compound (A-2) as the compound (A), the content ratio thereof is preferably about 20:80 to 80:20 in terms of mass ratio. The content ratio is more preferably about 30:70 to 70:30.

### <Phosphorus-Containing Compound (B)>

The resin composition of the present embodiment contains a phosphorus-containing compound (B) represented by the following Formula (2).

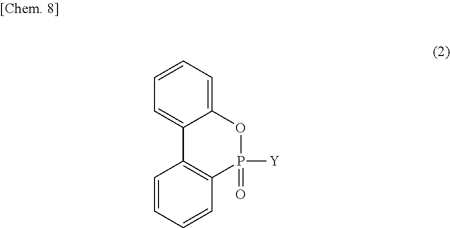

In Formula (2), Y represents a protecting group.

Since the phosphorus-containing compound (B) has a radical trapping effect, it is considered that a higher flame retardancy effect than before can be attained.

The resin composition of the present embodiment contains the phosphorus-containing compound (B) and is advantageous not only in flame retardancy but also in that a cured product thereof exhibits low dielectric properties.

The protecting group in the phosphorus-containing compound (B) refers to a substituent that is temporarily introduced into a specific functional group in a compound having the functional group thereby inactivating reactivity of the compound on the premise that the protecting group is eliminated at a later stage, and as a result of this, the chemical stability of the compound is enhanced. In the present embodiment, the later stage refers to the time when the resin composition containing the compound is combusted.

As the protecting group used in the present embodiment, any protecting group can be used without any particular problem as long as it is introduced with use of a protecting reagent. Such protective reagents refer to those generally available (e.g., commercially available) or those derived by a synthesizable protective reagent.

Specifically, examples of the protecting group Y include: silyl group, acyl group, allyl group, allyloxycarbonyl group, benzyl group, benzyloxycarbonyl group, acetal group, thioacetal group, 2,2,2-trichloroethoxycarbonyl group, alkoxymethyl group, tert-butoxycarbonyl group, 9-fluorenylmethyloxycarbonyl group, trityl group, and sulfonyl group. In particular, among these groups, the group is preferable such that the total molecular weight is 250 or more, and when the bond between X and Y is cleaved, as with the radical atom of X, the radical atom of Y is also a group that is stabilized by resonance with at least one adjacent aromatic ring to easily generate a stable radical.

Furthermore, the protecting group Y is preferably a group represented by the following Formula (3).

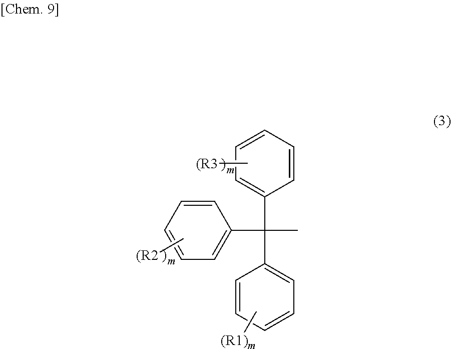

In Formula (3), R1, R2, and R3 each independently represent hydrogen, a benzoyloxy group, a vinylbenzyl group, an alkoxy group having 1 to 6 carbon atoms, or an alkenyl group having 2 to 6 carbon atoms, and m's each independently represent an integer from 1 to 5.

In a case where the protecting group Y in the phosphorus-containing compound (B) is a group represented by Formula (3), it is considered that each radical atom generated by cleavage of the organic compound is stabilized by resonance with at least one aromatic ring on one side (on the side of X) and three aromatic rings on the other side (on the side of protecting group Y), so that cleavage into a radical pair proceeds more smoothly. Therefore, the above-described flame retardant effect can be more reliably exhibited.

More specific examples of the group represented by Formula (3) include a trityl group, a 4-methoxytrityl group, a 4,4′-dimethoxytrityl group, and a 4,4′,4″-tris(benzoyloxy)trityl group.

For example, when the protecting group is a trityl group, the compound (A) of the present embodiment is as follows (provided that, compounds (1-2) to (1-4) other than a compound (1-1) are each a reference compound):

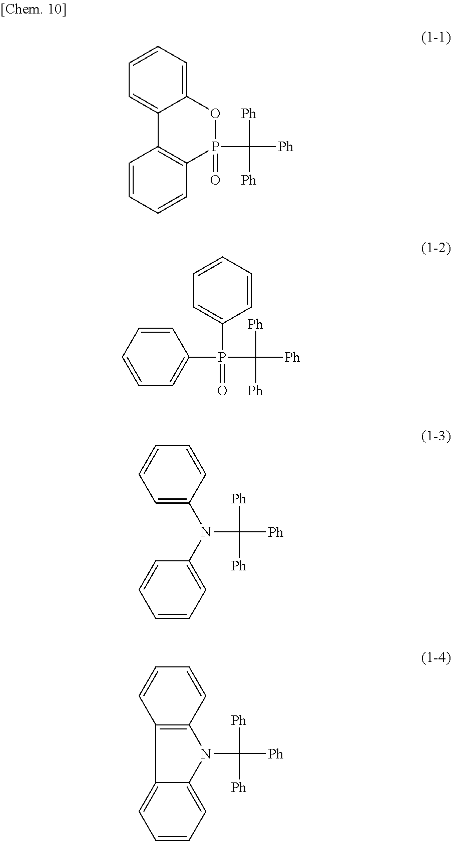 [SMILES: O=P1(C(c2ccccc2)(c2ccccc2)c2ccccc2)Oc2ccccc2-c2ccccc21 ; O=P(c1ccccc1)(c1ccccc1)C(c1ccccc1)(c1ccccc1)c1ccccc1 ; c1ccc(N(c2ccccc2)C(c2ccccc2)(c2ccccc2)c2ccccc2)cc1 ; c1ccc(C(c2ccccc2)(c2ccccc2)n2c3ccccc3c3ccccc32)cc1]

For example, when the protecting group is a 4-methoxytrityl group, the phosphorus-containing compound (B) of the present embodiment is as follows (provided that, compounds (2-2) to (2-4) other than a compound (2-1) are each a reference compound):

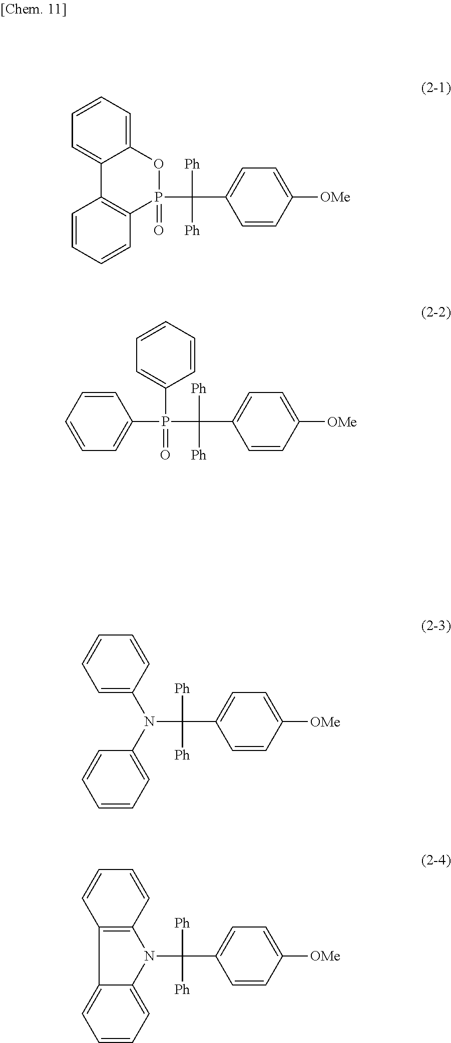 [SMILES: COc1ccc(C(c2ccccc2)(c2ccccc2)P2(=O)Oc3ccccc3-c3ccccc32)cc1 ; COc1ccc(C(c2ccccc2)(c2ccccc2)P(=O)(c2ccccc2)c2ccccc2)cc1 ; COc1ccc(C(c2ccccc2)(c2ccccc2)N(c2ccccc2)c2ccccc2)cc1 ; COc1ccc(C(c2ccccc2)(c2ccccc2)n2c3ccccc3c3ccccc32)cc1]

For example, when the protecting group is a 4,4′-dimethoxytrityl group, the phosphorus-containing compound (B) of the present embodiment is as follows (provided that, compounds (3-2) to (3-4) other than a compound (3-1) are each a reference compound):

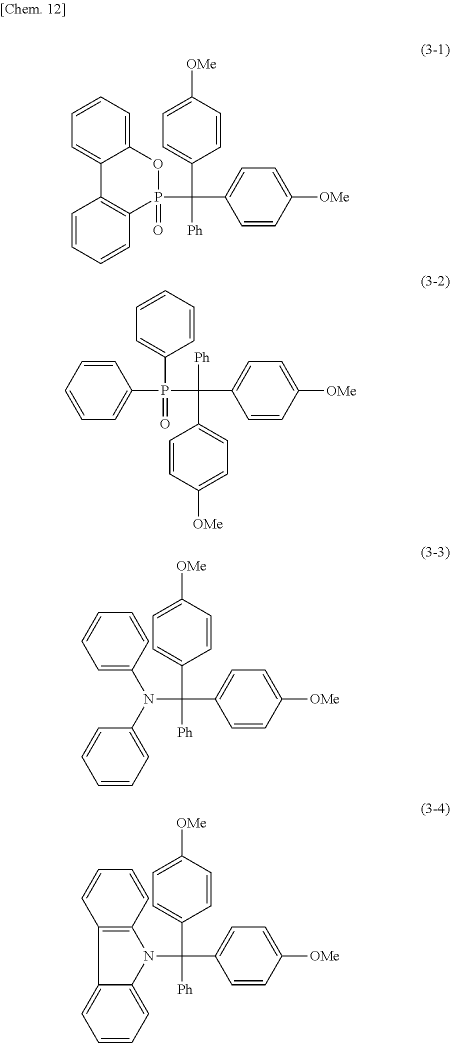

Furthermore, when the protecting group is a 4,4′,4″-tris(benzoyloxy)trityl group, the phosphorus-containing compound (B) of the present embodiment is as follows (provided that, compounds (4-2) to (4-4) other than a compound (4-1) are each a reference compound):

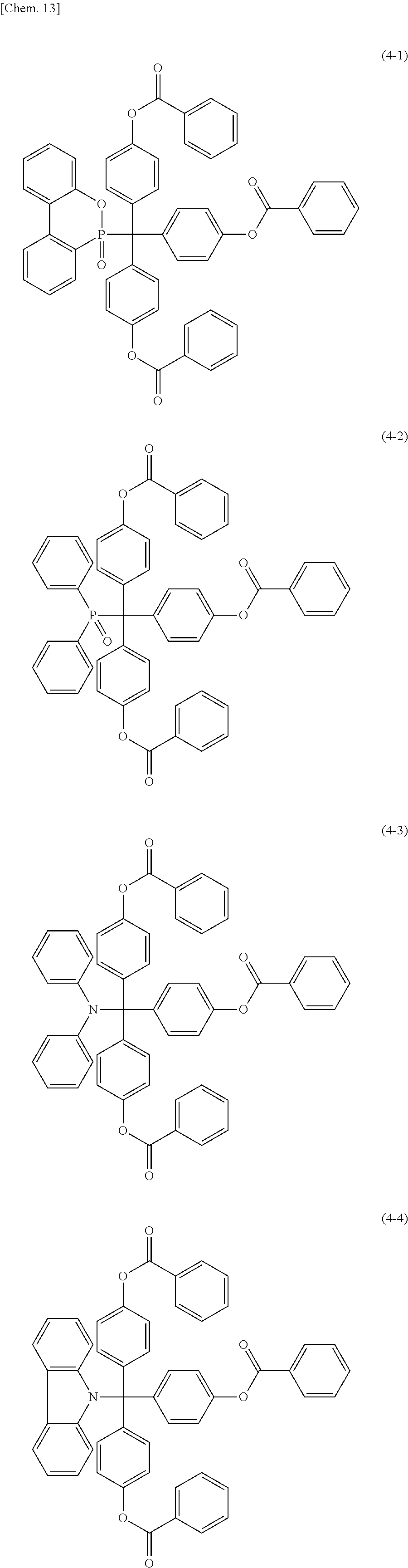 [SMILES: O=C(Oc1ccc(C(c2ccc(OC(=O)c3ccccc3)cc2)(c2ccc(OC(=O)c3ccccc3)cc2)P2(=O)Oc3ccccc3-c3ccccc32)cc1)c1ccccc1 ; O=C(Oc1ccc(C(c2ccc(OC(=O)c3ccccc3)cc2)(c2ccc(OC(=O)c3ccccc3)cc2)P(=O)(c2ccccc2)c2ccccc2)cc1)c1ccccc1 ; O=C(Oc1ccc(C(c2ccc(OC(=O)c3ccccc3)cc2)(c2ccc(OC(=O)c3ccccc3)cc2)N(c2ccccc2)c2ccccc2)cc1)c1ccccc1 ; O=C(Oc1ccc(C(c2ccc(OC(=O)c3ccccc3)cc2)(c2ccc(OC(=O)c3ccccc3)cc2)n2c3ccccc3c3ccccc32)cc1)c1ccccc1]

The phosphorus-containing compound (B) of the present embodiment preferably has a weight average molecular weight of 250 or more. As a result, the compound (A) is also advantageous in that volatility can be suppressed even when added and mixed into a synthetic resin at a high temperature and the addition effect thereof can be sufficiently exhibited. Furthermore, the weight average molecular weight of the phosphorus-containing compound (B) is more preferably 300 or more, still more preferably 400 or more. The upper limit of the molecular weight is not particularly limited, but is preferably 1000 or less, and more preferably 900 or less from the viewpoint of the number of radical sources per molecular weight.

The method of synthesizing the phosphorus-containing compound (B) of the present embodiment is not particularly limited, but for example, the phosphorus-containing compound (B) of the present embodiment can be obtained by a condensation reaction between 9,10-dihydro-9-oxa-10-phosphaphenanthrene-10-yl-10-oxide and a protective reagent having a group that specifically reacts with a functional group in the compound in the presence or absence of a base. Specific examples of the protective reagent that can be used include: 4-methoxytrityl chloride, 4,4′-dimethoxytrityl chloride, and 4,4′,4″-tris(benzoyloxy)trityl bromide.

### <Phosphorus-Containing Compound (C)>

The resin composition of the present embodiment may further contain a phosphorus-containing compound (C) having two or more diphenylphosphine oxide groups or 9,10-dihydro-9-oxa-10-phosphaphenanthrene-10-yl-10-oxide (DOPO) groups in the molecule. The diphenylphosphine oxide group is as represented below:

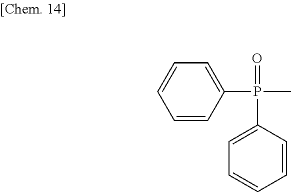

The DOPO group is as represented below:

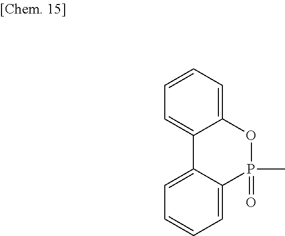 [SMILES: CP1(=O)Oc2ccccc2-c2ccccc21]

By containing such a phosphorus-containing compound (C), it is considered that a cured product of the resin composition of the present embodiment can exhibit high adhesive properties in addition to low dielectric properties and flame retardancy.

The phosphorus-containing compound (C) having two or more diphenylphosphine oxide groups or 9,10-dihydro-9-oxa-10-phosphaphenanthrene-10-yl-10-oxide (DOPO) groups in the molecule is not particularly limited as long as it is a phosphorus-containing compound having two or more diphenylphosphine oxide groups or 9,10-dihydro-9-oxa-10-phosphaphenanthrene-10-yl-10-oxide (DOPO) groups in the molecule. For example, the phosphorus-containing compound (C) may have a linking group that links two or more diphenylphosphine oxide groups or DOPO groups in the molecule, and the linking group may include at least one selected from the group consisting of a phenylene group, a xylylene group, a biphenylene group, a naphthylene group, a methylene group, and an ethylene group.

More specifically, examples include compounds represented by the following Formulas (C-1) to (C-3).

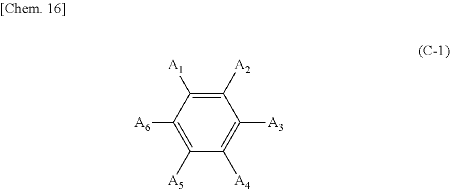

In Formula (C-1), two of A₁ to A₆ represent a diphenylphosphine oxide group or a 9,10-dihydro-9-oxa-10-phosphaphenanthrene-10-yl-10-oxide (DOPO) group; and the remaining four of A₁ to A₆ are the same as or different from each other and each represent a hydrogen atom, a methyl group, or a methoxy group.

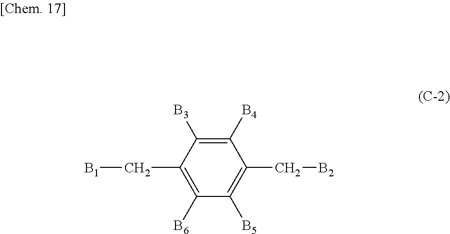

In Formula (C-2), B₁ and B₂ represent a diphenylphosphine oxide group or a 9,10-dihydro-9-oxa-10-phosphaphenanthrene-10-yl-10-oxide (DOPO) group; and B₃ to B₆ are the same as or different from each other and each represent a hydrogen atom, a methyl group, or a methoxy group.

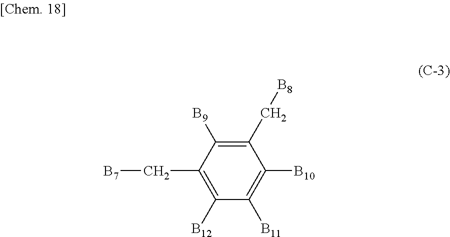

In Formula (C-3), 11₇ and Bs represent a diphenylphosphine oxide group, and B₉ to B₁₂ are the same as or different from each other and each represent a hydrogen atom, a methyl group, or a methoxy group.

More specifically, examples include 1,3-phenylene bis(diphenyl phosphate), compounds represented by the following Formulas (C-4) and (C-5), and 6,6′-(1-phenylethane-1,2-diyl)bis(6H-dibenzo[c,e][1,2]oxaphosphonine) 6,6′-dioxide (Di-DOPO) represented by the following Formula (C-6).

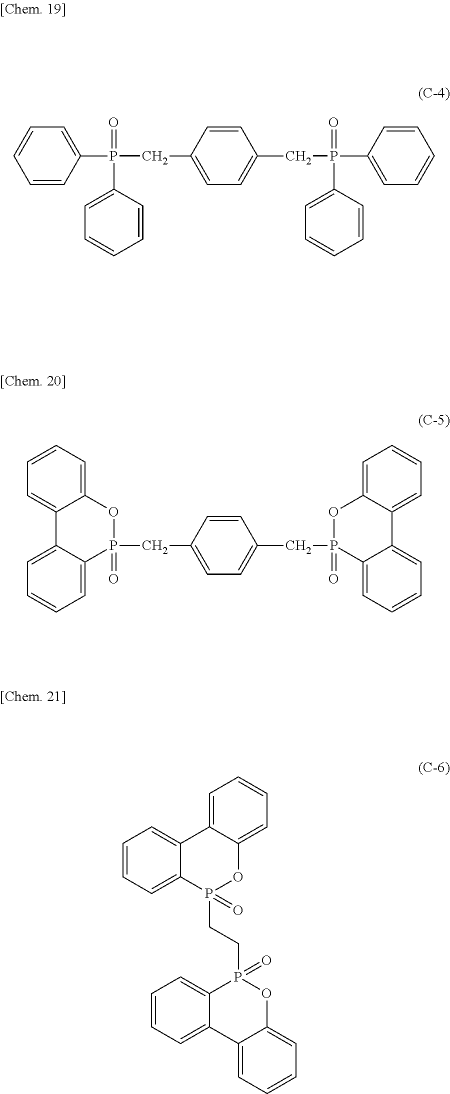 [SMILES: O=P(Cc1ccc(CP(=O)(c2ccccc2)c2ccccc2)cc1)(c1ccccc1)c1ccccc1 ; O=P1(Cc2ccc(CP3(=O)Oc4ccccc4-c4ccccc43)cc2)Oc2ccccc2-c2ccccc21 ; O=P1(CCP2(=O)Oc3ccccc3-c3ccccc32)Oc2ccccc2-c2ccccc21]

The resin composition of the present embodiment may further contain a reactive compound (D) exhibiting reactivity with the compound (A). By containing such a reactive compound (D), it is considered that there are advantages such as improved flame retardancy, increased glass transition temperature, and improved copper foil peel strength.

Specific examples of the reactive compound (D) include at least one compound selected from the group consisting of modified polyphenylene ether having a carbon-carbon unsaturated group, an acenaphthylene compound, a maleimide compound, and a polyfunctional hydrocarbon-based compound having a carbon-carbon unsaturated group other than the compound (A).

As the modified polyphenylene ether, a polyphenylene ether compound having a reactive carbon-carbon unsaturated double bond is used. For example, since it is preferable to use a terminal-modified polyphenylene ether compound that can exert excellent low dielectric properties when cured, it is preferable to use a modified polyphenylene ether compound of which the terminal is modified with a substituent having a carbon-carbon unsaturated double bond.

Examples of the substituent having a carbon-carbon unsaturated double bond include a group having a styrene structure or a (meth)acrylate structure as represented by the following formula (8) or (9).

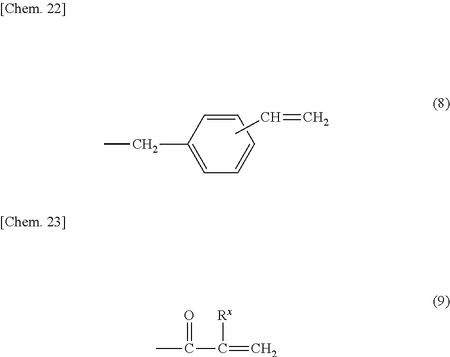

In Formula (9), RX represents a hydrogen atom or an alkyl group. The alkyl group is not particularly limited and is, for example, preferably an alkyl group having 1 to 18 carbon atoms, more preferably an alkyl group having 1 to 10 carbon atoms. Specific examples thereof include a methyl group, an ethyl group, a propyl group, a hexyl group, and a decyl group.

More specifically, examples of the substituent include: vinylbenzyl group (ethenylbenzyl group) such as p-ethenylbenzyl group and m-ethenylbenzyl group, vinylphenyl group, acrylate group, and methacrylate group.

It is considered that by using the modified polyphenylene ether compound like this, low dielectric properties such as low dielectric constant and low dielectric loss tangent and excellent heat resistance can be maintained and also higher Tg and adhesive properties can be enhanced.

One kind of the modified polyphenylene ether compounds can be used singly, or two or more kinds thereof can be used in combination.

In the present embodiment, the weight average molecular weight (Mw) of the modified polyphenylene ether compound used as a thermosetting resin is not particularly limited, but is, for example, preferably 1000 to 5000, more preferably 1000 to 4000. The weight average molecular weight may be measured by a general molecular weight measurement method, and specific examples thereof include a value measured by gel permeation chromatography (GPC). In a case where the modified polyphenylene ether compound has repeating units (s, m, and n) in the molecule, these repeating units are preferably numerical values such that the weight average molecular weight of the modified polyphenylene ether compound falls within this range.

When the weight average molecular weight of the modified polyphenylene ether compound is within such a range, the excellent low dielectric properties of the polyphenylene ether skeleton are exhibited and a cured product exhibiting not only superior heat resistance but also excellent moldability is afforded. This is considered to be due to the following. In comparison with a typical polyphenylene ether, the modified polyphenylene ether compound having a weight average molecular weight within a range set forth above has a relatively low molecular weight, and hence the heat resistance of the cured product tends to decrease. With this regard, the modified polyphenylene ether compound according to the present embodiment has a styrene structure or a (meth)acrylate structure at the terminal and hence has a high reactivity, and it is considered to afford a cured product whose heat resistance is sufficiently high. When the weight average molecular weight of the modified polyphenylene ether compound is within the range like this, the modified polyphenylene ether compound has a higher molecular weight than that of styrene or divinylbenzene but has a relatively lower molecular weight than that of typical polyphenylene ether, and hence it is considered that the modified polyphenylene ether compound is excellent in moldability as well. Therefore, the modified polyphenylene ether compound like this is considered to afford a cured product excellent not only in heat resistance but also excellent in moldability.

In the modified polyphenylene ether compound used as the thermosetting resin in the present exemplary embodiment, the average number of the substituents (the number of terminal functional groups) included at the molecular terminal per molecule of the modified polyphenylene ether is not particularly limited. Specifically, the number of terminal functional groups is preferably 1 to 5, more preferably 1 to 3. When the number of terminal functional groups is too small, it tends to be difficult to obtain a cured product exhibiting sufficient heat resistance. When the number of terminal functional groups is too large, the reactivity is too high, and for example, there is a possibility that troubles such as a deterioration in storage stability of the resin composition and a decrease in fluidity of the resin composition may occur. In other words, there is a possibility that the use of such a modified polyphenylene ether causes moldability problems in that, for example, molding defects such as voids are generated during multilayer molding by poor fluidity and the like and it is difficult to obtain a highly reliable printed wiring board.

The number of terminal functional groups in the modified polyphenylene ether compound includes a numerical value representing the average value of the substituents per molecule of all modified polyphenylene ether compounds present in 1 mole of the modified polyphenylene ether compound. This number of terminal functional groups can be determined by, for example, calculating the decrease from the number of hydroxyl groups in the polyphenylene ether before modification to the number of hydroxyl groups remaining in the resulting modified polyphenylene ether compound. The number of hydroxyl groups decreased from the number of hydroxyl groups in the polyphenylene ether before being modified is the number of terminal functional groups. With regard to the method for measuring the number of hydroxyl groups remaining in the modified polyphenylene ether compound, the number of hydroxyl groups can be determined by adding a quaternary ammonium salt (tetraethylammonium hydroxide) to be associated with a hydroxyl group to a solution of the modified polyphenylene ether compound and measuring the UV absorbance of the mixed solution.

The polyphenylene ether compound used in the resin composition of the present embodiment can be synthesized by a known method, or a commercially available polyphenylene ether compound can also be used. Examples of the commercially available product include: “OPE-2st 1200” and “OPE-2st 2200” manufactured by Mitsubishi Gas Chemical Company Inc., and “SA 9000” manufactured by SABIC Innovative Plastics.

In the present embodiment, as the acenaphthylene compound, any acenaphthylene compound can be used without particular limitation as long as it is a compound having an acenaphthylene structure in the molecule. Specifically, examples of the acenaphthylene compound include acenaphthylene, alkylacenaphthylenes, halogenated acenaphthylenes, and phenylacenaphthylenes.

Examples of the alkyl acenaphthylenes include 1-methyl acenaphthylene, 3-methyl acenaphthylene, 4-methyl acenaphthylene, 5-methyl acenaphthylene, 1-ethyl acenaphthylene, 3-ethyl acenaphthylene, 4-ethyl acenaphthylene, and 5-ethyl acenaphthylene. Examples of the halogenated acenaphthylenes include 1-chloroacenaphthylene, 3-chloroacenaphthylene, 4-chloroacenaphthylene, 5-chloroacenaphthylene, 1-bromoacenaphthylene, 3-bromoaccnaphthylene, 4-bromoacenaphthylene, and 5-bromoacenaphthylene. Examples of the phenylacenaphthylenes include 1-phenylacenaphthylene, 3-phenylacenaphthylene, 4-phenylacenaphthylene, and 5-phenylacenaphthylene. The acenaphthylene compound may be a monofunctional acenaphthylene compound having one acenaphthylene structure in the molecule as described above or may be a polyfunctional acenaphthylene compound having two or more acenaphthylene structures in the molecule.

As the maleimide compound usable in the present embodiment, any compound having a maleimide group in the molecule can be used without particular limitation. Specifically, examples of the maleimide compound include: monofunctional maleimide compounds having one maleimide group in the molecule, polyfunctional maleimide compounds having two or more maleimide groups in the molecule, and modified malcimide compounds. Examples of the polyfunctional maleimide compound include aromatic maleimide compounds containing an aromatic group in the molecule, imide group-containing maleimide compounds having an imide group in the molecule, aliphatic maleimide compounds containing a long-chain alkyl group in the molecule, maleimide compounds containing an indane structure in the molecule, maleimide compounds having an arylene structure, which is bonded by being oriented at the meta position, in the molecule. Examples of the modified maleimide compound include a modified malcimide compound in which a part of the molecule is modified with an amine compound, a modified maleimide compound in which a part of the molecule is modified with a silicone compound, and a modified maleimide compound in which a part of the molecule is modified with an amine compound and a silicone compound.

Examples of the indane structure contained in the maleimide compound include the structure represented by Formula (7), and examples of the maleimide compound containing an indane structure in the molecule include a maleimide compound represented by the following Formula (M-1).

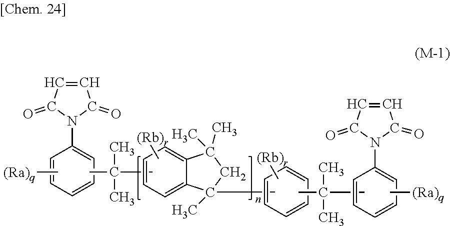

[In Formula (M-1), Ra's each independently represent an alkyl group having 1 to 10 carbon atoms, an alkyloxy group having 1 to 10 carbon atoms, an alkylthio group having 1 to 10 carbon atoms, an aryl group having 6 to 10 carbon atoms, an aryloxy group having 6 to 10 carbon atoms, an arylthio group having 6 to 10 carbon atoms, a cycloalkyl group having 3 to 10 carbon atoms, a halogen atom, a nitro group, a hydroxyl group, or a mercapto group. Rb's each independently represent an alkyl group having 1 to 10 carbon atoms, an alkyloxy group having 1 to 10 carbon atoms, an alkylthio group having 1 to 10 carbon atoms, an aryl group having 6 to 10 carbon atoms, an aryloxy group having 6 to 10 carbon atoms, an arylthio group having 6 to 10 carbon atoms, a cycloalkyl group having 3 to 10 carbon atoms, a halogen atom, a nitro group, a hydroxyl group, or a mercapto group. q represents an integer from 0 to 4, r represents an integer from 0 to 3, and n represents an integer from 0.95 to 10.]

The maleimide compound used in the present embodiment may be a commercially available product, and for example, the solid components in MIR-3000-70MT and MIR-5000-60T manufactured by Nippon Kayaku Co., Ltd.; BMI-4000, BMI-2300, BMI-5100, and BMI-TMH manufactured by Daiwa Fine Chemicals Co., Ltd.; and BMI-689, BMI-1500, BMI-3000J, and BMI-5000 manufactured by Designer Molecules Inc. may be used.

The polyfunctional hydrocarbon-based compound having a carbon-carbon unsaturated group other than the compound (A), which is used in the present embodiment is not particularly limited as long as it is a polyfunctional hydrocarbon-based compound, which is a compound other than the compound (A) and has a carbon-carbon unsaturated group. Specific examples include cyclic olefin compounds such as divinylbenzene, polybutadiene, styrene butadiene oligomer, ethylene propylene diene rubber (EPDM), and cycloolefin polymer (COP).

### <Styrenic Elastomer (E)>

The resin composition of the present embodiment may further contain a styrenic elastomer (E). This has the advantage of lowering the dielectric loss tangent and improving the copper foil peel strength.

The styrenic elastomer (E) that can be used in the present embodiment is a polymer obtained by polymerizing a monomer including a styrenic monomer, and may be a styrenic copolymer. Examples of the styrenic copolymer include: copolymers obtained by copolymerizing one or more styrenic monomers and one or more of other monomers copolymerizable with the styrenic monomers. The styrenic copolymer may be a random copolymer or a block copolymer as long as a structure derived from the styrenic monomer is included in the molecule. Examples of the block copolymer include a bipolymer of the structure (repeating unit) derived from the styrenic monomer and the other copolymerizable monomer (repeating unit) and a terpolymer of the structure (repeating unit) derived from the styrenic monomer, the other copolymerizable monomer (repeating unit), and the structure (repeating unit) derived from the styrenic monomer.

The styrenic elastomer (E) may be a hydrogenated styrenic copolymer obtained by hydrogenating the styrenic copolymer.

As the styrenic elastomer (E), one styrenic polymer may be used singly, or two or more kinds thereof may be used in combination.

The styrenic elastomer (E) preferably has a weight average molecular weight of 1000 to 300000, more preferably 1200 to 200000. When the molecular weight is too low, the glass transition temperature or heat resistance of the cured product of the resin composition tends to decrease. When the molecular weight is too high, the viscosity of the resin composition when prepared in the form of a varnish and the viscosity of the resin composition during heat molding tend to be too high. The weight average molecular weight is only required to be one measured by a general molecular weight measurement method, and specific examples thereof include a value measured by gel permeation chromatography (GPC).

As the styrenic elastomer (E), commercially available products can be used, and for example, “SEPTON (registered trademark) V9827”, “SEPTON (registered trademark) 2063” and the like manufactured by Kuraray Co., Ltd.; “FTR (registered trademark) 2140”, “FTR (registered trademark) 6125” and the like manufactured by Mitsui Chemicals, Inc.; “Tuftec (registered trademark) H1517” and the like manufactured by Asahi Kasei Corporation; and “DYNARON (registered trademark) 9901P” and the like manufactured by JSR Corporation may be used.

### <Content>

The content of the compound (A) in the resin composition of the present embodiment is preferably 20 to 80 parts by mass with respect to 100 parts by mass of the total of the compound (A) and the phosphorus-containing compound (B). It is considered that the above-described effects can be thus attained more reliably. A more preferred range is 30 to 70 parts by mass.

The phosphorus-containing compound (B) is preferably contained so that the phosphorus content in the entire resin composition is about 2 to 4 mass %. Furthermore, in a case where the resin composition of the present embodiment contains the phosphorus-containing compound (C) in addition to the phosphorus-containing compound (B), it is preferable that the phosphorus-containing compound (B) and the phosphorus-containing compound (C) are contained so that the total phosphorus content therein is in the above range.

In a case where the phosphorus-containing compound (C) is contained, the content of the phosphorus-containing compound (C) is preferably 30 to 70 parts by mass with respect to 100 parts by mass of the total of the phosphorus-containing compound (B) and the phosphorus-containing compound (C). It is considered that the balance between low dielectric properties and flame retardancy and adhesive properties is thus more favorable.

In a case where the resin composition of the present embodiment contains the reactive compound (D), it is preferable to adjust the content thereof so that the content of the compound (A) is 20 to 80 parts by mass with respect to 100 parts by mass of the total of the compound (A) and the reactive compound (D). It is considered that the above-mentioned effects achieved by containing the reactive compound (D) are thus attained more reliably.

In a case where the resin composition of the present embodiment contains the styrenic elastomer (E), the content thereof is preferably adjusted to 5 to 30 parts by mass with respect to 100 parts by mass of the total of the compound (A), the reactive compound (D) and the styrenic elastomer (E). It is considered that the above-mentioned effects achieved by containing the styrenic elastomer (E) are thus attained more reliably.

### (Inorganic Filler)

The resin composition according to the present embodiment may further contain an inorganic filler. The inorganic filler is not particularly limited and includes those added to enhance the heat resistance and flame retardancy of the cured product of a resin composition. By containing an inorganic filler, it is considered that heat resistance, flame retardancy and the like can be further enhanced as well as the coefficient of thermal expansion can be kept lower (achievement of even lower thermal expansion properties).

Specific examples of the inorganic filler that can be used in the present embodiment include metal oxides such as silica, alumina, titanium oxide, magnesium oxide, and mica, metal hydroxides such as magnesium hydroxide and aluminum hydroxide, talc, aluminum borate, barium sulfate, aluminum nitride, boron nitride, barium titanate, strontium titanate, calcium titanate, aluminum titanate, barium zirconate titanate, barium zirconate, calcium zirconate, zirconium phosphate, zirconium tungstate phosphate, magnesium carbonate such as anhydrous magnesium carbonate, calcium carbonate, and boehmite-treated products thereof. Among these, silica, metal hydroxides such as magnesium hydroxide and aluminum hydroxide, aluminum oxide, boron nitride, and barium titanate, strontium titanate and the like are preferable, and silica is more preferable. The silica is not particularly limited, and examples thereof include crushed silica, spherical silica, and silica particles.

These inorganic fillers may be used singly or in combination of two or more kinds thereof. An inorganic filler as described above may be used as it is, but one subjected to a surface treatment with an epoxysilane-type, vinylsilane-type, methacrylsilane-type, phenylaminosilane-type, or aminosilane-type silane coupling agent may be used. The silane coupling agent can be used by being added to the filler by an integral blend method instead of the method of treating the surface of the filler with the silane coupling agent in advance.

In a case where the resin composition of the present embodiment contains an inorganic filler, the content thereof is preferably 10 to 300 parts by mass, more preferably 40 to 250 parts by mass with respect to 100 parts by mass of the total of the compound (A), the phosphorus-containing compound (B), the phosphorus-containing compound (C), and the reactive compound (D).

### <Other Components>

The resin composition according to the present embodiment may contain components (other components) in addition to the components described above if necessary as long as the effects of the present invention are not impaired. As the other components contained in the resin composition according to the present embodiment, for example, additives such as catalysts such as reaction initiators and reaction accelerators, silane coupling agents, polymerization inhibitors, polymerization retarders, free radical compounds, flame retardants other than the phosphorus-containing compounds (B) and (C), flame retardant auxiliaries, defoamers, leveling agents, antioxidants, heat stabilizers, antistatic agents, ultraviolet absorbers, dyes and pigments, dispersants, and lubricants.

The resin composition according to the present embodiment may contain a reaction initiator (catalyst) and a reaction accelerator as described above. The reaction initiator and reaction accelerator are not particularly limited as long as they can promote the curing reaction of the resin composition. Specifically, examples thereof include metal oxides, azo compounds, peroxides, imidazole compounds, phosphorus-based curing accelerators, and amine-based curing accelerators.

(Prepreg, Film with Resin, Metal-Clad Laminate, Wiring Board, and Metal Foil with Resin)

Next, a prepreg for wiring board, a metal-clad laminate, a wiring board, and a metal foil with resin obtained using the resin composition of the present embodiment will be described.

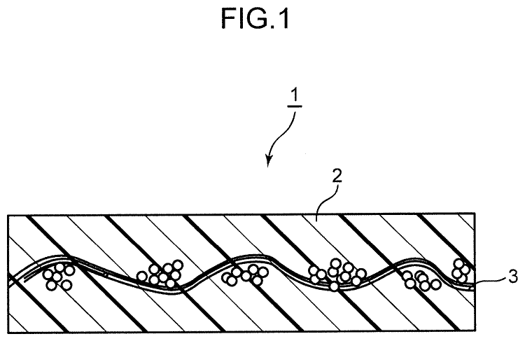

FIG. 1 is a schematic sectional view illustrating an example of a prepreg 1 according to an embodiment of the present invention. The respective symbols in the drawings indicate the following: 1 prepreg, 2 resin composition or semi-cured product of resin composition, 3 fibrous base material, 11 metal-clad laminate, 12 insulating layer, 13 metal foil, 14 wiring, 21 wiring board, 31 metal foil with resin, 32, 42 resin layer, 41 film with resin, and 43 support film.

As illustrated in FIG. 1, the prepreg 1 according to the present embodiment includes the resin composition or a semi-cured product 2 of the resin composition and a fibrous base material 3. Examples of the prepreg 1 include those in which the fibrous base material 3 is present in the resin composition or a semi-cured product 2 thereof. In other words, the prepreg 1 includes the resin composition or semi-cured product thereof; and the fibrous base material 3 present in the resin composition or semi-cured product 2 thereof.

In the present embodiment, the “semi-cured product” is one in a state in which the resin composition is partially cured so as to be further cured. In other words, the semi-cured product is the resin composition in a semi-cured state (B-staged). For example, when a resin composition is heated, the viscosity of the resin composition first gradually decreases, then curing starts, and the viscosity gradually increases. In such a case, semi-curing includes the state between after the viscosity starts to increase and before the resin composition is completely cured.

The prepreg obtained using the resin composition according to the present embodiment may include a semi-cured product of the resin composition as described above, or may include the uncured resin composition itself. In other words, the prepreg may be a prepreg including a semi-cured product of the resin composition (the resin composition in B stage) and a fibrous base material, or may be a prepreg including the resin composition before curing (the resin composition in A stage) and a fibrous base material. Specific examples of the prepreg include those in which a fibrous base material is present in the resin composition. The resin composition or semi-cured product thereof may be one obtained by heating and drying the resin composition.

When the prepreg and the metal foil with resin, metal-clad laminate and the like to be described later are fabricated, the resin composition according to the present embodiment is often prepared in the form of a varnish and used as a resin varnish. Such a resin varnish is prepared, for example, as follows.

First, the respective components that can be dissolved in an organic solvent, such as a resin component and a reaction initiator, are put into an organic solvent and dissolved. At this time, heating may be performed, if necessary. Thereafter, the phosphorus-containing compound (B), the phosphorus-containing compound (C), the inorganic filler and the like, which are components that are not dissolved in an organic solvent, are added to and dispersed in the solution until a predetermined dispersion state is achieved using a ball mill, a bead mill, a planetary mixer, a roll mill or the like, whereby a varnish-like resin composition is prepared. The organic solvent used here is not particularly limited as long as it dissolves the compound (A), the reactive compound (D) and the like and does not inhibit the curing reaction. Specific examples thereof include toluene, methyl ethyl ketone, cyclohexanone, cyclopentanone, methylcyclohexane, dimethylformamide, and propylene glycol monomethyl ether acetate. These may be used singly or two or more kinds thereof may be used concurrently.

Examples of the method for fabricating the prepreg 1 of the present embodiment using the varnish-like resin composition of the present embodiment include a method in which the fibrous base material 3 is impregnated with the resin composition 2 in the form of a resin varnish and then drying is performed.

Specific examples of the fibrous base material used in fabrication of the prepreg include glass cloth, aramid cloth, polyester cloth, LCP (liquid crystal polymer) nonwoven fabric, glass nonwoven fabric, aramid nonwoven fabric, polyester nonwoven fabric, pulp paper, and linter paper. When glass cloth is used, a laminate exhibiting excellent mechanical strength is obtained, and glass cloth subjected to flattening is particularly preferable. The glass cloth used in the present embodiment is not particularly limited, but examples thereof include glass cloth with low dielectric constant such as E glass, S glass, NE glass, Q glass, and L glass. Specifically, the flattening can be carried out, for example, by continuously pressing the glass cloth with press rolls at an appropriate pressure to flatten the yarn. As for the thickness of the fibrous base material, for example, a fibrous base material having a thickness of 0.01 to 0.3 mm can be generally used.

Impregnation of the fibrous base material 3 with the resin varnish (resin composition 2) is performed by dipping, coating, or the like. This impregnation can be repeated multiple times if necessary. At this time, it is also possible to repeat impregnation using a plurality of resin varnishes having different compositions and concentrations, and adjust the composition (content ratio) and resin amount to the finally desired values.

The fibrous base material 3 impregnated with the resin varnish (resin composition 2) is heated under desired heating conditions, for example, at 80° C. or more and 180° C. or less for 1 minute or more and 10 minutes or less. By heating, the solvent is volatilized from the varnish and the solvent is diminished or removed to obtain the prepreg 1 before curing (in A stage) or in a semi-cured state (B stage).

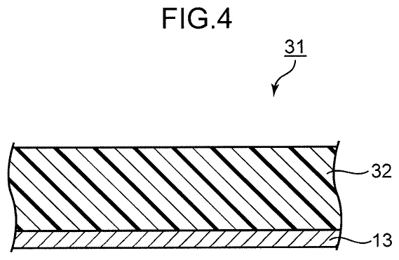

As illustrated in FIG. 4, a metal foil with resin 31 of the present embodiment has a configuration in which a resin layer 32 containing the resin composition described above or a semi-cured product of the resin composition; and a metal foil 13 are laminated. In other words, the metal foil with resin of the present embodiment may be a metal foil with resin including a resin layer containing the resin composition before curing (the resin composition in A stage) and a metal foil, or may be a metal foil with resin including a resin layer containing a semi-cured product of the resin composition (the resin composition in B stage) and a metal foil.

Examples of the method for fabricating such a metal foil with resin 31 include a method in which a resin composition in the form of a resin varnish as described above is applied to the surface of the metal foil 13 such as a copper foil and then dried. Examples of the application method include a bar coater, a comma coater, a die coater, a roll coater, and a gravure coater.

As the metal foil 13, metal foils used in metal-clad laminates, wiring boards and the like can be used without limitation, and examples thereof include copper foil and aluminum foil.

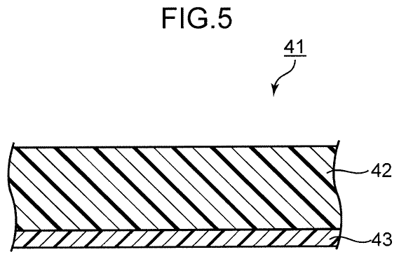

As illustrated in FIG. 5, a film with resin 41 of the present embodiment has a configuration in which a resin layer 42 containing the resin composition described above or a semi-cured product of the resin composition; and a film supporting base material 43 are laminated. In other words, the film with resin of the present embodiment may be a film with resin including the resin composition before curing (the resin composition in A stage); and a film supporting base material, or a film with resin including a semi-cured product of the resin composition (the resin composition in B stage); and a film supporting base material.

As the method for fabricating such a film with resin 41, for example, a resin composition in the form of a resin varnish as described above is applied to the surface of the film supporting base material 43, and then the solvent is volatilized from the varnish and diminished or removed, whereby a film with resin before curing (A stage) or in a semi-cured state (B stage) can be obtained.

Examples of the film supporting base material include electrical insulating films such as a polyimide film, a PET (polyethylene terephthalate) film, a polyethylene naphthalate film, a polyester film, a poly(parabanic acid) film, a polyether ether ketone film, a polyphenylene sulfide film, an aramid film, a polycarbonate film, and a polyarylate film.

In the film with resin and metal foil with resin of the present embodiment, the resin composition or semi-cured product thereof may be one obtained by drying or heating and drying the resin composition as in the prepreg described above.

The thickness and the like of the metal foil 13 and the film supporting base material 43 can be appropriately set depending on the desired purpose. For example, as the metal foil 13, a metal foil having a thickness of about 0.2 to 70 μm can be used. In a case where the thickness of metal foil is, for example, 10 μm or less, the metal foil may be a carrier-attached copper foil including a release layer and a carrier in order to improve handleability. The application of the resin varnish to the metal foil 13 and the film supporting base material 43 is performed by coating or the like, and this can be repeated multiple times if necessary. At this time, it is also possible to repeat coating using a plurality of resin varnishes having different compositions and concentrations, and adjust the composition (content ratio) and resin amount to the finally desired values.

Drying or heating and drying conditions in the fabrication method of the metal foil with resin 31 and film with resin 41 are not particularly limited, but a resin composition in the form of a resin varnish is applied to the metal foil 13 and film supporting base material 43, and then heating is performed under desired heating conditions, for example, at 50° C. to 180° C. for about 0.1 to 10 minutes to volatilize the solvent from the varnish and diminish or remove the solvent, whereby the metal foil with resin 31 and film with resin 41 before curing (A stage) or in a semi-cured state (B stage) are obtained.

The metal foil with resin 31 and film with resin 41 may include a cover film and the like, if necessary. By including a cover film, it is possible to prevent foreign matter from entering. The cover film is not particularly limited as long as it can be peeled off without damaging the form of the resin composition, and for example, a polyolefin film, a polyester film, a TPX film, films formed by providing a release agent layer on these films, and paper obtained by laminating these films on a paper substrate can be used.

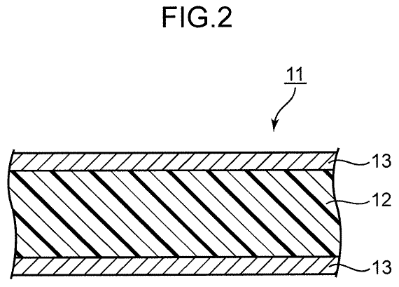

As illustrated in FIG. 2, a metal-clad laminate 11 of the present embodiment includes an insulating layer 12 containing a cured product of the resin composition described above or a cured product of the prepreg described above; and a metal foil 13. As the metal foil 13 used in the metal-clad laminate 11, a metal foil similar to the metal foil 13 described above can be used.

The metal-clad laminate 11 of the present embodiment can also be fabricated using the metal foil with resin 31 or film with resin 41 described above.

As the method for fabricating a metal-clad laminate using the prepreg 1, metal foil with resin 31, or film with resin 41 obtained in the manner described above, one or a plurality of prepregs 1, metal foils with resin 31, or films with resin 41 are superimposed on one another, and the metal foils 13 such as copper foil are further superimposed on both upper and lower sides or on one side, and this is laminated and integrated by heating and pressing, whereby a double-sided metal-clad or single-sided metal-clad laminate can be fabricated. The heating and pressing conditions can be appropriately set depending on the thickness of the laminate to be fabricated, the kind of the resin composition, and the like, but for example, the temperature may be set to 170° C. to 230° C., the pressure may be set to 1.5 to 5.0 MPa, and the time may be set to 60 to 150 minutes.

The metal-clad laminate 11 may be fabricated by forming a film-like resin composition on the metal foil 13 without using the prepreg 1 or the like and performing heating and pressing.

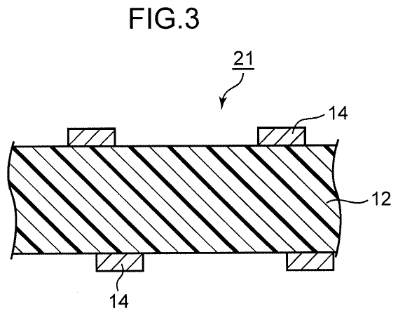

As illustrated in FIG. 3, a wiring board 21 of the present embodiment includes wiring 14 and an insulating layer 12 containing a cured product of the resin composition described above or a cured product of the prepreg described above.

The resin composition of the present embodiment is suitably used as a material for an insulating layer of a wiring board. As the method for fabricating the wiring board 21, for example, the metal foil 13 on the surface of the metal-clad laminate 11 obtained above is etched to form a circuit (wiring), whereby the wiring board 21 having a conductor pattern (wiring 14) provided as a circuit on the surface of a laminate can be obtained. Examples of the circuit forming method include circuit formation by a semi additive process (SAP) or a modified semi additive process (MSAP) in addition to the method described above.

The prepreg, film with resin, and metal foil with resin obtained using the resin composition of the present embodiment are extremely useful in industrial applications since the cured products thereof exhibit excellent low dielectric properties and high flame retardancy. The metal-clad laminate and wiring board obtained by curing these also exhibit low dielectric properties and high flame retardancy.

This specification discloses techniques in various aspects as described above, and the main techniques among them are summarized below.

A resin composition according to a first aspect of the present invention contains a compound (A) containing at least one selected from a polyfunctional vinyl aromatic copolymer (A-1), which has a repeating unit (a1) derived from a divinyl aromatic compound and a repeating unit (a2) derived from a monovinyl aromatic compound and contains the repeating unit (a1) at 2 mol % or more and less than 95 mol % and the repeating unit (a2) at 5 mol % or more and less than 98 mol % when a total of the repeating unit (a1) and the repeating unit (a2) is set to 100 mol %, or a hydrocarbon-based compound (A-2) represented by Formula (1); and a phosphorus-containing compound (B) represented by Formula (2).

A resin composition according to a second aspect of the present invention is the resin composition according to the first aspect, in which the protecting group is a group represented by Formula (3).

A resin composition according to a third aspect of the present invention is the resin composition according to the first or second aspect, further containing a phosphorus-containing compound (C) represented by Formula (4).

A resin composition according to a fourth aspect of the present invention is the resin composition according to any one of the first to third aspects, in which a content of the phosphorus-containing compound (C) is 30 to 70 parts by mass with respect to 100 parts by mass of a total of the phosphorus-containing compound (B) and the phosphorus-containing compound (C).

A resin composition according to a fifth aspect of the present invention is the resin composition according to any one of the first to fourth aspects, in which the compound (A) contains the polyfunctional vinyl aromatic copolymer (A-1) and the hydrocarbon-based compound (A-2).

A resin composition according to a sixth aspect of the present invention is the resin composition according to any one of the first to fifth aspects, containing at least one reactive compound (D) selected from the group consisting of modified polyphenylene ether having a carbon-carbon unsaturated group, an acenaphthylene compound, a maleimide compound, and a polyfunctional hydrocarbon-based compound having a carbon-carbon unsaturated group other than the compound (A).

A resin composition according to a seventh aspect of the present invention is the resin composition according to the sixth aspect, in which a content of the compound (A) is 20 to 80 parts by mass with respect to 100 parts by mass of a total of the compound (A) and the reactive compound (D).

A resin composition according to an eighth aspect of the present invention is the resin composition according to any one of the first to seventh aspects, in which the hydrocarbon-based compound (A-2) includes a hydrocarbon-based compound (A-2a) represented by Formula (5).

A resin composition according to a ninth aspect of the present invention is the resin composition according to any one of the first to eighth aspects, further containing a styrenic elastomer (E).

A prepreg according to a tenth aspect of the present invention includes the resin composition according to any one of the first to ninth aspects or a semi-cured product of the resin composition; and a fibrous base material.

A film with resin according to an eleventh aspect of the present invention includes a resin layer containing the resin composition according to any one of the first to ninth aspects or a semi-cured product of the resin composition; and a support film.

A metal foil with resin according to a twelfth aspect of the present invention includes a resin layer containing the resin composition according to any one of the first to ninth aspects or a semi-cured product of the resin composition; and a metal foil.

A metal-clad laminate according to a thirteenth aspect of the present invention includes an insulating layer containing a cured product of the resin composition according to any one of the first to ninth aspects or a cured product of the prepreg according to the tenth aspect; and a metal foil.

A wiring board according to a fourteenth aspect of the present invention includes an insulating layer containing a cured product of the resin composition according to any one of the first to ninth aspects or a cured product of the prepreg according to the tenth aspect; and a wiring.

Hereinafter, the present invention will be described more specifically with reference to Examples, but the scope of the present invention is not limited thereto.

### EXAMPLES

First, the components to be used in the preparation of resin compositions in the present Examples will be described.

### <Polyfunctional Vinyl Aromatic Polymer (A-1)>

A polyfunctional vinyl aromatic polymer was obtained based on the following method: Into a 5.0 L reactor, 3.0 mole (390.6 g) of divinylbenzene, 1.8 mole (229.4 g) of ethylvinylbenzene, 10.2 mole (1066.3 g) of styrene and 15.0 mole (1532.0 g) of n-propyl acetate were charged, 600 mmole of boron trifluoride diethyl ether complex was added at 70° C., and the reaction was conducted for 4 hours. After the polymerization solution was terminated with an aqueous sodium bicarbonate solution, the oil layer was washed three times with pure water and volatilized under reduced pressure at 60° C. to recover the solid (polymer). The obtained solid was weighed and found to be 896.7 g.

The structure of the obtained solid (polymer) was measured by ¹³C-NMR and ¹H-NMR analysis using a nuclear magnetic resonance spectrometer, Model JNM-LA600 manufactured by JEOL Ltd. Chloroform-dI was used as the solvent and the resonance line of tetramethylsilane was used as the internal standard. In addition to the ¹³C-NMR and ¹H-NMR measurement results, the amount of a specific structural unit introduced was calculated from the data on the total amount of the respective structural units introduced into the copolymer acquired by GC analysis, and the amount of the pendant vinyl group units contained in the polyfunctional vinyl aromatic copolymer was calculated from the amount of the specific structural unit introduced at the terminal and the number average molecular weight acquired by the GPC measurement.

The obtained solid was subjected to ¹³C-NMR and ¹H-NMR analysis as described above to observe resonance lines derived from each monomer unit. Based on the results of NMR measurement and the results of GC analysis, it was found that this solid was the polyfunctional vinyl aromatic copolymer. The structural units of this polyfunctional vinyl aromatic copolymer were calculated as follows based on the results of NMR measurement and the results of GC analysis. The structural unit derived from divinylbenzene was 30.4 mol % (33.1 mass %), the structural unit derived from styrene was 57.4 mol % (52.7 mass %), the structural unit derived from ethylvinylbenzene was 12.2 mol % (14.2 mass %), and the structural unit having a residual vinyl group, which was derived from divinylbenzene, was 23.9 mol % (25.9 mass %).

The molecular weight and molecular weight distribution of the obtained solid (polyfunctional vinyl aromatic copolymer) were measured using tetrahydrofuran as a solvent and a calibration curve created using monodisperse polystyrene at a flow rate of 1.0 ml/min and a column temperature of 38° C. using GPC (HLC-8120GPC manufactured by Tosoh Corporation). As a result, the obtained solid had a number average molecular weight Mn of 2980, a weight average molecular weight Mw of 41300, and Mw/Mn of 13.9.

### <Hydrocarbon-Based Compound (A-2)>

### (Production of Hydrocarbon-Based Compound 1)

First, the weight average molecular weight (Mw) and number average molecular weight (Mn) used in the production of hydrocarbon-based compound 1 below are values determined by the following analysis method.

### (Analysis Method)

The molecular weights were calculated in terms of polystyrene using a polystyrene standard solution.
GPC: DGU-20A3R, LC-20AD, SIL-20AHT, RID-20A, SPD-20A, CTO-2, CBM-20A
(all manufactured by Shimadzu Corporation)
Column: Shodex KF-603, KF-602x2, KF-601x2)
Coupled cluent: Tetrahydrofuran
Flow velocity: 0.5 ml/min.
Column temperature: 40° C.
Detection: RI (differential refraction detector)

### Synthesis Example 1

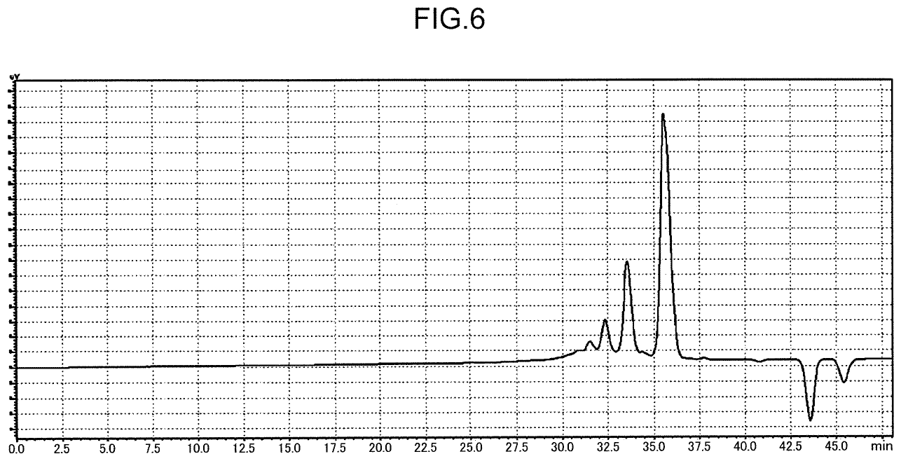

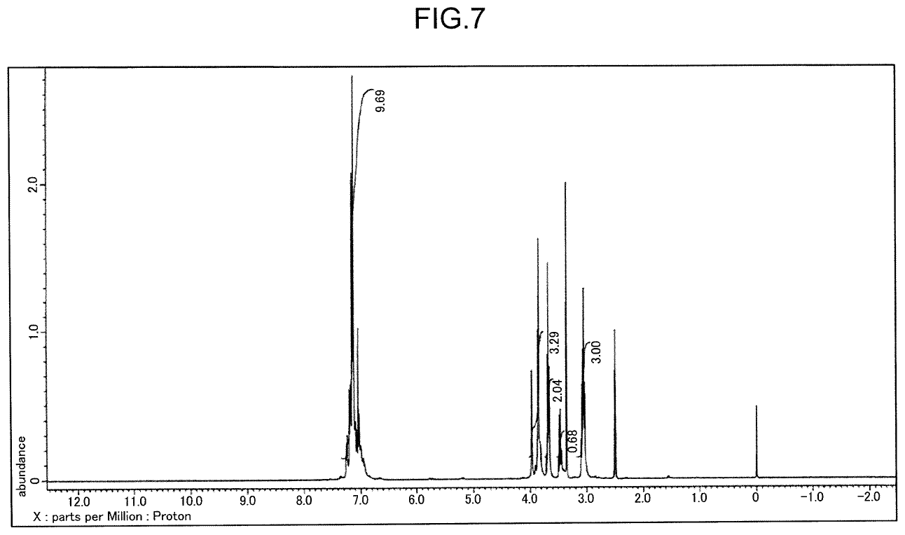

Into a flask equipped with a thermometer, a condenser, and a stirrer, 296 parts of 2-bromoethylbenzene (manufactured by Tokyo Chemical Industry Co., Ltd.), 70 parts of α,α′-dichloro-p-xylene (manufactured by Tokyo Chemical Industry Co., Ltd.), and 18.4 parts of methanesulfonic acid (manufactured by Tokyo Chemical Industry Co., Ltd.) were introduced, and the reaction was conducted at 130° C. for 8 hours. After being left to cool, the reaction mixture was neutralized with an aqueous sodium hydroxide solution, and subjected to extraction with 1200 parts of toluene, and the organic layer was washed with 100 parts of water five times. The solvent and excess 2-bromoethylbenzene were distilled off under heating and reduced pressure to obtain 160 parts of an olefin compound precursor (BEB-1) having a 2-bromoethylbenzene structure as a liquid resin (Mn: 538, Mw: 649). A GPC chart of the obtained compound is illustrated in FIG. 6. The repeating unit n calculated from the area % in the GPC chart was 1.7. A ¹H-NMR chart (DMSO-d6) of the obtained compound is illustrated in FIG. 7. Signals attributed to a bromoethyl group were observed at 2.95 to 3.15 ppm and 3.60 to 3.75 ppm on the ¹H-NMR chart.

### Synthesis Example 2

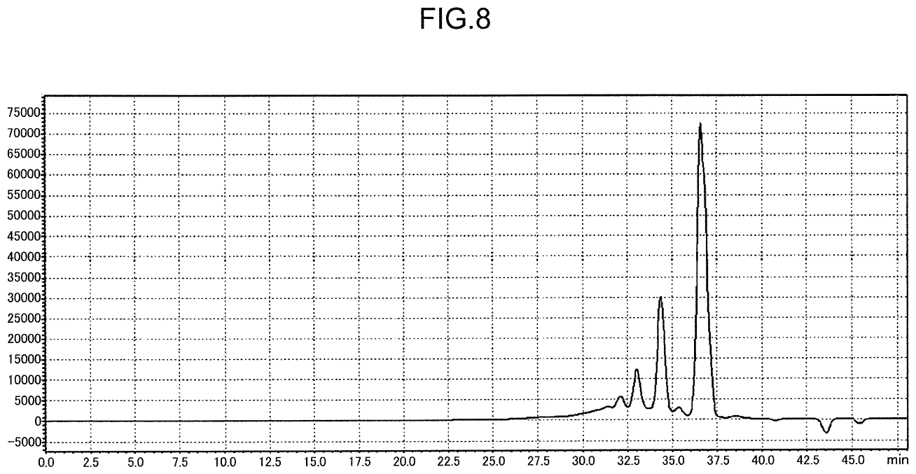

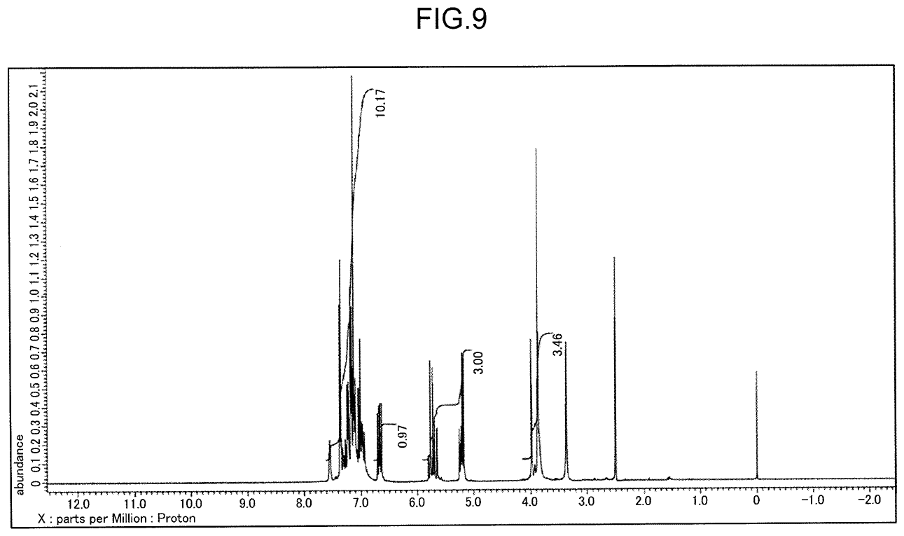

Next, 22 parts of BEB-1 obtained in Synthesis Example 1, 50 parts of toluene, 150 parts of dimethyl sulfoxide, 15 parts of water and 5.4 parts of sodium hydroxide were introduced into a flask equipped with a thermometer, a condenser, and a stirrer, and the reaction was conducted at 40° C. for 5 hours. After standing to cool, 100 parts of toluene was added, the organic layer was washed with 100 parts of water five times, and the solvent was distilled off under heating and reduced pressure to obtain 13 parts of a liquid olefin compound having a styrene structure as a functional group (Mn: 432, Mw: 575). A GPC chart of the obtained compound is illustrated in FIG. 8. The repeating unit n calculated from the area % in the GPC chart was 1.7. A ¹H-NMR data (DMSO-d6) of the obtained compound is illustrated in FIG. 9. Signals attributed to a vinyl group were observed at 5.10 to 5.30 ppm, 5.50 to 5.85 ppm, and 6.60 to 6.80 ppm on the ¹H-NMR chart.

The liquid olefin compound was referred to as hydrocarbon-based compound 1.

### <Synthesis of Phosphorus-Containing Compound (B)>

Production of 9,10-dihydro-9-oxa-10-phosphaphenanthrene-10-trityl-10-oxide (Organic compound 1)

Into a 300 ml inner volume four-necked flask of hard glass equipped with a stirrer, a thermometer, a reflux condenser, and a gas inlet port were charged 21.6 g (Mw 216.2×0.1 mol) of 9,10-dihydro-9-oxa-10-phosphaphenanthrene-10-oxide and 183 g of acetonitrile.

While blowing nitrogen gas from the gas inlet port, the temperature was raised, and at the time when the temperature raised up to 70° C., trityl chloride was started to be added portionwise.

After 9.3 g of the first portion of trityl chloride had been added, thereafter an operation of adding 9.3 g of trityl chloride was repeated per hour, and a total amount of 27.9 g (Mw 278.8×0.1 mol) of trityl chloride was added portionwise.

After the portionwise addition had been completed, the temperature of the reactor was set to 80° C., the mixture underwent dehydrochlorination aging reaction for 24 hours, and then cooling was started. At the time when the reactor temperature went down to about 25° C., the precipitated crystals were filtrated under reduced pressure, and then the filtrated crystals were washed with purified water, and the washing operation was continued until the filtrate showed almost neutral pH, followed by drying.

Through the above operations, 44.4 g of white crystal of organic compound 1 (Mw 458.5) having a melting point of about 250° C. was obtained.

This organic compound 1 was found to have a purity of 99% by liquid chromatographic (LC) analysis, and the obtained organic compound 1 was found to be a phosphorus-containing compound (B) having the following chemical structure by its infrared (IR) absorption spectrum, ¹H-NMR, and FD-MS analysis.

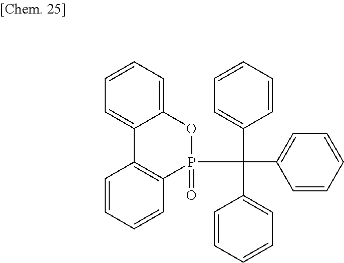 [SMILES: O=P1(C(c2ccccc2)(c2ccccc2)c2ccccc2)Oc2ccccc2-c2ccccc21]

### <Phosphorus-Containing Compound (C)>

Phosphorus-containing compound (C): DOPO-based compound (phosphorus-containing compound having two or more DOPO groups in molecule; “Di-DOPO” manufactured by Life Chemicals, Inc.)

### <Another Phosphorus-Containing Compound>

Phosphorus-containing compound: Phosphine oxide compound (“PQ-60” manufactured by Shinichi Chemical Co., Ltd.)

### <Reactive Compound (D): Modified Polyphenylene Ether Compound>

Modified PPE: Modified polyphenylene ether obtained by reacting polyphenylene ether with chloromethylstyrene. Specifically, this is modified polyphenylene ether obtained by conducting a reaction as follows.

First, 200 g of polyphenylene ether (SA90 manufactured by SABIC Innovative Plastics Co., Ltd., number of terminal hydroxyl groups: 2, weight average molecular weight Mw 1700), 30 g of a mixture containing p-chloromethylstyrene and m-chloromethylstyrene at a mass ratio of 50:50 (chloromethylstyrene: CMS manufactured by Tokyo Chemical Industry Co., Ltd.), 1.227 g of tetra-n-butylammonium bromide as a phase transfer catalyst, and 400 g of toluene were introduced into a 1-liter three-necked flask equipped with a temperature controller, a stirrer, cooling equipment, and a dropping funnel and stirred. Then, the mixture was stirred until polyphenylene ether, chloromethylstyrene, and tetra-n-butylammonium bromide were dissolved in toluene. At that time, the mixture was gradually heated until the liquid temperature finally reached 75° C. Then, an aqueous sodium hydroxide solution (20 g of sodium hydroxide/20 g of water) as an alkali metal hydroxide was added dropwise to the solution over 20 minutes. Thereafter, the mixture was further stirred at 75° C. for 4 hours. Next, the resultant in the flask was neutralized with hydrochloric acid at 10 mass % and then a large amount of methanol was added into the flask. By doing so, a precipitate was generated in the liquid in the flask. In other words, the product contained in the reaction solution in the flask was reprecipitated. Then, this precipitate was taken by filtration and washed three times with a liquid mixture of methanol and water at a mass ratio of 80:20, and then dried at 80° C. under reduced pressure for 3 hours.

The obtained solid was analyzed by ¹H-NMR (400 MHz, CDCl₃, TMS). As a result of NMR measurement, a peak attributed to ethenylbenzyl was confirmed at 5 to 7 ppm. This confirmed that the obtained solid was polyphenylene ether in which the terminals of the molecule were ethenylbenzylated.

The number of terminal functional groups in the modified polyphenylene ether was measured as follows. First, the modified polyphenylene ether was accurately weighed. The weight at that time is defined as X (mg). Thereafter, this modified polyphenylene ether weighed was dissolved in 25 mL of methylene chloride, 100 μL of an ethanol solution of tetraethylammonium hydroxide (TEAH) at 10 mass % (TEAH:ethanol (volume ratio)=15:85) was added to the solution, and then the absorbance (Abs) of this mixture at 318 nm was measured using a UV spectrophotometer (UV-1600 manufactured by Shimadzu Corporation). Then, the number of terminal hydroxyl groups in the modified polyphenylene ether was calculated from the measurement results using the following equation.

$$Residual OH amount ( μmol / g ) = [ ( 25 \times Abs ) / ( ε \times OPL \times X ) ] \times {10}^{6}$$

In the present embodiment, c denotes the extinction coefficient and is 4700 L/mol·cm. OPL denotes the cell optical path length and is 1 cm.

Since the calculated residual OH amount (the number of terminal hydroxyl groups) in the modified polyphenylene ether is almost zero, it was found that the hydroxyl groups in the polyphenylene ether before being modified are almost modified. From this fact, it was found that the number of terminal hydroxyl groups decreased from the number of terminal hydroxyl groups in polyphenylene ether before being modified was the number of terminal hydroxyl groups in polyphenylene ether before being modified. In other words, it was found that the number of terminal hydroxyl groups in polyphenylene ether before being modified was the number of terminal functional groups in the modified polyphenylene ether. In other words, the number of terminal functional groups was 2.

In addition, an intrinsic viscosity (IV) of the modified polyphenylene ether was measured in methylene chloride at 25° C. Specifically, the intrinsic viscosity (IV) of the modified polyphenylene ether was measured in a methylene chloride solution (liquid temperature: 25° C.) of the modified polyphenylene ether at 0.18 g/45 ml using a viscometer (AVS500 Visco System manufactured by SCHOTT Instruments GmbH). As a result, the intrinsic viscosity (IV) of the modified polyphenylene ether was 0.086 dl/g.

The molecular weight distribution of the modified polyphenylene ether was measured by GPC. Moreover, the weight average molecular weight (Mw) was calculated from the obtained molecular weight distribution. As a result, Mw was 2300.

### <Reactive Compound (D): Acenaphthylene Compound>

Acenaphthylene (manufactured by FE Chemical Corporation)

### <Styrenic Elastomer (E)>

Hydrogenated styrene-ethylene-butylene-styrene (“DYNARON 9901P” manufactured by JSR Corporation)

### <Inorganic Filler>

DENKA FUSED SILICA LOW DIELECTRIC LOSS TANGENT TYPE (manufactured by Denka Company Limited, spherical silica)

### Examples 1 to 7 and Comparative Examples 1 to 3

### [Preparation Method]

### (Resin Varnish)

First, the respective components were added to and mixed in toluene at the blending proportions (parts by mass) presented in Table 1 so that the solid concentration of the resin component was 60 mass %. The obtained mixture was stirred for 60 minutes. Thereafter, the respective phosphorus-containing compounds and an inorganic filler were added to the obtained mixture and dispersed in advance using a stirrer, and then the filler was dispersed using a bead mill. By doing so, a varnish-like resin composition (varnish) was obtained.

The phosphorus content (P content) in each of Examples and Comparative Examples is a value (%) determined by multiplying the weight of each phosphorus compound contained by the phosphorus content in each phosphorus compound, adding the values thus acquired, and then dividing the sum by the total mass of components other than the inorganic filler (silica).

### (Fabrication of Evaluation Substrate)

A prepreg and an evaluation substrate (metal-clad laminate) were obtained as follows.

First, the obtained varnish was impregnated into a fibrous base material (glass cloth: #1078 type, L2 Glass manufactured by Asahi Kasei Corporation) and then heated and dried at 120° C. for 3 minutes, thereby fabricating a prepreg having a resin thickness of 75 μm. At that time, the content (resin content) of the components constituting the resin composition with respect to the prepreg was adjusted to be about 64 mass % by the curing reaction.

Next, an evaluation substrate (metal-clad laminate) was obtained as follows.

Two or ten sheets of each of the obtained prepregs were stacked, and copper foil (“CF-T4X-SV” manufactured by FUKUDA METAL FOIL & POWDER CO., LTD., copper foil thickness: 18 μm) was disposed on both sides of the stacked body. This as a body to be pressed was heated to a temperature of 220° C. at a rate of temperature rise of 3° C./min and heated and pressed under the conditions of 220° C., 120 minutes, and a pressure of 3 MPa, thereby obtaining an evaluation substrate (metal-clad laminate) having copper foil bonded to both surfaces and having a resin layer thickness of about 150 μm or 750 μm.

The evaluation substrates (metal-clad laminates) fabricated as described above were used to conduct evaluation tests by the following methods.

### <Evaluation Test 1>

### (Dielectric Properties: Dielectric Loss Tangent (Df))

The relative dielectric constant and dielectric loss tangent at 10 GHz were measured by a cavity perturbation method using an unclad plate obtained by removing the copper foil from the evaluation substrate (metal-clad laminate) having a thickness of 150 μm by etching as a test piece. Specifically, the dielectric loss tangent of the evaluation substrate at 10 GHz was measured using a network analyzer (N5230A manufactured by Keysight Technologies). In the present test, it is determined as acceptable when the Df is 0.0015 or less.

### (Flame Retardancy Evaluation)

Using an unclad plate obtained by removing the copper foil from the evaluation substrate with a thickness of 750 μm obtained above by etching, the combustibility (average seconds) was evaluated in conformity with the combustibility test of UL 94. Specifically, the average seconds until the fire went out was measured in a total of 10 times of flame application in which a test flame was applied twice to five evaluation substrates, the average value thereof was calculated, and the maximum seconds were also recorded. As the evaluation criteria, it was determined as acceptable when the average seconds were 7 seconds or less and the maximum seconds were 20 seconds or less. The numerical values on the left side of the table indicate the average seconds, and the numerical values on the right side indicate the maximum seconds.

The results are presented in Table 1.

TABLE 1

| | | Example | Example | Example | Example | Example |
|---|---|---|---|---|---|---|
| Composition (parts by mass) | | 1 | 2 | 3 | 4 | 5 |
| Compound (A) | Polyfunctional vinyl aromatic | 40 | 20 | 20 | 20 | 20 |
| | polymer (A-1) | | | | | |
| | Hydrocarbon-based | | 20 | 20 | 20 | 20 |
| | compound (A-2) | | | | | |
| Reactive compound (D) | Modified PPE compound | 25 | 25 | 25 | 25 | 25 |
| | Acenaphthylene | 20 | 20 | 20 | 20 | 20 |
| Elastomer (E) | Styrenic elastomer | 15 | 15 | 15 | 15 | 15 |
| Phosphorus-containing compound | Compound (B) | 106 | 30 | 23.2 | 40 | 20 |
| (B) | | | | | | |
| Phosphorus-containing compound | Di-DOPO | | 18.4 | 14.2 | 14.6 | 22.2 |
| (C) | | | | | | |
| Another phosphorus-containing | PQ-60 | | | | | |
| compound | | | | | | |
| Inorganic filler | Silica | 60 | 60 | 60 | 60 | 60 |
| P content | | 3.5 | 3 | 2.5 | 3 | 3 |
| Evaluation | | | | | | |
| Df | @10 GHz | 0.0013 | 0.0013 | 0.0013 | 0.0013 | 0.0014 |
| Flame retardancy | Average seconds/Maximum | 4.0/6.7 | 5.7/11 | 6.4/15.4 | 5.1/12.6 | 5.7/11.8 |
| | seconds | | | | | |
| | | | | Compar- | Compar- | Compar- |
| | | | | ative | ative | ative |
| | | Example | Example | Exam- | Exam- | Exam- |
| Composition (parts by mass) | | 6 | 7 | ple 1 | ple 2 | ple 3 |
| Compound (A) | Polyfunctional vinyl aromatic | 20 | 23.6 | 40 | | 40 |
| | polymer (A-1) | | | | | |
| | Hydrocarbon-based | 20 | 23.5 | | 40 | |
| | compound (A-2) | | | | | |
| Reactive compound (D) | Modified PPE compound | 25 | 29.4 | 25 | 25 | 25 |
| | Acenaphthylene | 20 | 23.5 | 20 | 20 | 20 |
| Elastomer (E) | Styrenic elastomer | 15 | | 15 | 15 | 15 |
| Phosphorus-containing compound | Compound (B) | 34 | 20 | | | |
| (B) | | | | | | |
| Phosphorus-containing compound | Di-DOPO | 20 | 22.2 | | | |
| (C) | | | | | | |
| Another phosphorus-containing | PQ-60 | | | 41.6 | 41.6 | 33.7 |
| compound | | | | | | |
| Inorganic filler | Silica | 60 | 60 | 60 | 60 | 60 |
| P content | | 3.2 | 3 | 3.5 | 3.5 | 3 |
| Evaluation | | | | | | |
| Df | @10 GHz | 0.0014 | 0.0014 | 0.0014 | 0.0017 | 0.00127 |
| Flame retardancy | Average seconds/Maximum | 4.2/11.9 | 3.5/5.7 | 7.7/20.3 | 5.0/11.4 | 10.3/44.1 |
| | seconds | | | | | |

### (Discussion)

As is clear from the results presented in Table 1, it was found that a cured product exhibiting low dielectric properties and excellent flame retardancy in a well-balanced manner is obtained from the resin composition of the present invention. In contrast, in Comparative Examples in which a resin composition containing another phosphorus-containing compound instead of the phosphorus-containing compound (B) was used, it was found that the cured product does not exhibit both sufficient flame retardancy and low dielectric properties in a well-balanced manner.

### <Evaluation Test 2>

### (Glass Transition Temperature (Tg))

Using an unclad plate obtained by removing the copper foil from the evaluation substrate with a thickness of 150 μm obtained above by etching, Tg was measured using a viscoelastic spectrometer “DMS6100” manufactured by Seiko Instruments Inc. At this time, dynamic viscoelasticity measurement (DMA) was performed in a tensile module at a frequency of 10 Hz, and the temperature at which tan δ was maximized when the temperature was raised from room temperature to 350° C. at a rate of temperature rise of 5° C./min was taken as Tg. In the present test, it is determined as acceptable when the Tg is 200° C. or more.

### (Peel Strength)

The copper foil was peeled off from the evaluation substrates (metal-clad laminates) of Examples 1 to 3, and the peel strength at that time was measured in conformity with JIS C 6481. Specifically, the evaluation substrate was cut to have a width and a length of 10 mm, the copper foil was peeled off at a speed of 50 mm/min using a tensile tester, and the peel strength (N/mm) at that time was measured. In the present test, it is determined as acceptable when the peel strength is 0.25 N/mm or more.

The results are presented in Table 2.

TABLE 2

| Composition (parts by mass) | | Example 1 | Example 2 | Example 3 | Example 4 |
|---|---|---|---|---|---|
| Compound (A) | Polyfunctional vinyl aromatic polymer (A-1) | 40 | 20 | 20 | 20 |
| | Hydrocarbon-based compound (A-2) | | 20 | 20 | 20 |
| Reactive compound (D) | Modified PPE compound | 25 | 25 | 25 | 25 |
| | Acenaphthylene | 20 | 20 | 20 | 20 |
| Elastomer (E) | Styrenic elastomer | 15 | 15 | 15 | 15 |
| Phosphorus-containing compound (B) | Compound (B) | 106 | 30 | 23.2 | 40 |
| Phosphorus-containing compound (C) | Di-DOPO | | 18.4 | 14.2 | 14.6 |
| Inorganic filler | Silica | 60 | 60 | 60 | 60 |
| P content | | 3.5 | 3 | 2.5 | 3 |
| Evaluation | | | | | |
| Tg | (° C.) | 228 | 220 | 220 | 222 |
| Copper foil peel strength | (N/mm) | 0.14 | 0.32 | 0.38 | 0.29 |

| Composition (parts by mass) | | Example 5 | Example 6 | Example 7 |
|---|---|---|---|---|
| Compound (A) | Polyfunctional vinyl aromatic polymer (A-1) | 20 | 20 | 23.6 |
| | Hydrocarbon-based compound (A-2) | 20 | 20 | 23.5 |
| Reactive compound (D) | Modified PPE compound | 25 | 25 | 29.4 |
| | Acenaphthylene | 20 | 20 | 23.5 |
| Elastomer (E) | Styrenic elastomer | 15 | 15 | |
| Phosphorus-containing compound (B) | Compound (B) | 20 | 34 | 20 |
| Phosphorus-containing compound (C) | Di-DOPO | 22.2 | 20 | 22.2 |
| Inorganic filler | Silica | 60 | 60 | 60 |
| P content | | 3 | 3.2 | 3 |
| Evaluation | | | | |
| Tg | (° C.) | 215 | 219 | 223 |
| Copper foil peel strength | (N/mm) | 0.34 | 0.28 | 0.38 |

### (Discussion)

From the results in Table 2, it was found that a high Tg can be secured in Examples in which the composition of the present invention is used. It was also found that a cured product exhibiting higher adhesive properties is obtained by containing both the polyfunctional vinyl aromatic polymer (A-1) and the hydrocarbon-based compound (A-2) and containing both the phosphorus compounds (11) and (C).

This application is based on Japanese patent application No. 2022-180985 filed on Nov. 11, 2022, the contents of which are included in the present application.

In order to express the present invention, the present invention has been described above appropriately and sufficiently through the embodiments with reference to specific examples, drawings and the like. However, it should be recognized by those skilled in the art that changes and/or improvements of the above-described embodiments can be readily made. Accordingly, changes or improvements made by those skilled in the art shall be construed as being included in the scope of the claims unless otherwise the changes or improvements are at the level which departs from the scope of the appended claims.

### INDUSTRIAL APPLICABILITY

The present invention has wide industrial applicability in technical fields such as electronic materials, electronic devices, and optical devices.

1. A resin composition comprising:
a compound (A) containing at least one selected from a polyfunctional vinyl aromatic copolymer (A-1), which has a repeating unit (a1) derived from a divinyl aromatic compound and a repeating unit (a2) derived from a monovinyl aromatic compound and contains the repeating unit (a1) at 2 mol % or more and less than 95 mol % and the repeating unit (a2) at 5 mol % or more and less than 98 mol % when a total of the repeating unit (a1) and the repeating unit (a2) is set to 100 mol %, or a hydrocarbon-based compound (A-2) represented by the following Formula (1); and
a phosphorus-containing compound (B) represented by the following Formula (2): 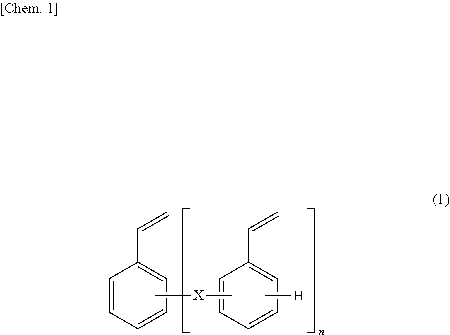
wherein, X represents a hydrocarbon group having 6 or more carbon atoms, which includes at least one selected from an aromatic cyclic group or an aliphatic cyclic group, and n represents an integer from 1 to 10; 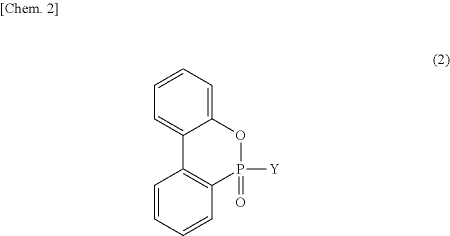
wherein, Y is a protecting group.

2. The resin composition according to claim 1, wherein
the protecting group is a group represented by the following Formula (3): 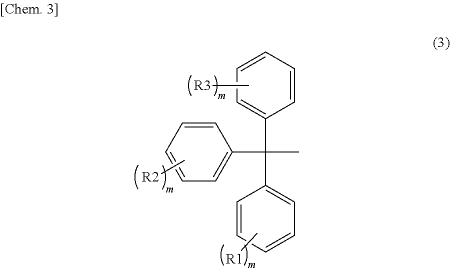
wherein, R1, R2, and R3 each independently represent hydrogen, a benzoyloxy group, a vinylbenzyl group, an alkoxy group having 1 to 6 carbon atoms, or an alkenyl group having 2 to 6 carbon atoms, and m's each independently represent an integer from 1 to 5.

3. The resin composition according to claim 1, comprising a phosphorus-containing compound (C) having two or more diphenylphosphine oxide groups or 9,10-dihydro-9-oxa-10-phosphaphenanthrene-10-yl-10-oxide groups in a molecule.

4. The resin composition according to claim 3, wherein a content of the phosphorus-containing compound (C) is 30 to 70 parts by mass with respect to 100 parts by mass of a total of the phosphorus-containing compound (B) and the phosphorus-containing compound (C).

5. The resin composition according to claim 1, wherein the compound (A) contains the polyfunctional vinyl aromatic copolymer (A-1) and the hydrocarbon-based compound (A-2).

6. The resin composition according to claim 1, comprising at least one reactive compound (D) selected from the group consisting of modified polyphenylene ether having a carbon-carbon unsaturated group, an acenaphthylene compound, a maleimide compound, and a polyfunctional hydrocarbon-based compound having a carbon-carbon unsaturated group other than the compound (A).

7. The resin composition according to claim 6, wherein a content of the compound (A) is 20 to 80 parts by mass with respect to 100 parts by mass of a total of the compound (A) and the reactive compound (D).

8. The resin composition according to claim 1, wherein the hydrocarbon-based compound (A-2) includes a hydrocarbon-based compound (A-2a) represented by the following Formula (5): 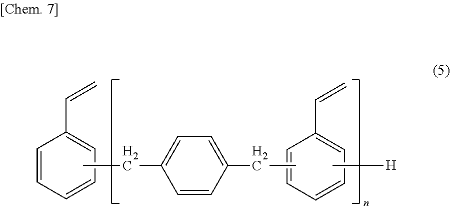
wherein, n represents an integer from 1 to 10.

9. The resin composition according to claim 1, comprising a styrenic elastomer (E).

10. A prepreg comprising:
the resin composition according to claim 1 or a semi-cured product of the resin composition; and
a fibrous base material.

11. A film with resin comprising:
a resin layer containing the resin composition according to claim 1 or a semi-cured product of the resin composition; and
a support film.

12. A metal foil with resin comprising:
a resin layer containing the resin composition according to claim 1 or a semi-cured product of the resin composition; and
a metal foil.

13. A metal-clad laminate comprising:
an insulating layer containing a cured product of the resin composition according to claim 1 and
a metal foil.

14. A wiring board comprising:
an insulating layer containing a cured product of the resin composition according to claim 1 and
a wiring.

15. A metal-clad laminate comprising:
an insulating layer containing a cured product of the prepreg according to claim 10; and
a metal foil.

16. A wiring board comprising:
an insulating layer containing a cured product of the prepreg according to claim 10; and
a wiring.
